(19) United States
(12) Patent Application Publication
(10) Pub. No.: US 2024/0153907 A1
(43) Pub. Date: May 9, 2024

(54) BONDING MATERIAL APPLICATION APPARATUS AND BONDING MATERIAL APPLICATION METHOD

(71) Applicant: FUJI ELECTRIC CO., LTD., Kawasaki-shi (JP)

(72) Inventor: Narumi SATO, Matsumoto-city (JP)

(73) Assignee: FUJI ELECTRIC CO., LTD., Kawasaki-shi (JP)

(21) Appl. No.: 18/474,864

(22) Filed: Sep. 26, 2023

(30) Foreign Application Priority Data
Nov. 9, 2022 (JP) 2022-179636

(51) Int. Cl. H01L 23/00; H01L 21/683

(52) U.S. Cl. CPC H01L 24/743; H01L 21/6838; H01L 24/27; H01L 2224/27; H01L 2224/743

(57) ABSTRACT

An apparatus includes a base having a stage region at a front side thereof, and a plurality of suction holes in the stage region; an elastic member provided in the stage region and having a plurality of through holes, each of which is disposed at a position immediately above a corresponding one suction hole when viewed from a suction direction from the front side to a rear side of the base; and a suction unit configured to apply suction for suctioning a target member to be placed in the stage region through the suction holes in the suction direction, thereby to fix the target member to the stage region by the suction via the elastic member.

### CROSS-REFERENCE TO RELATED APPLICATION

This application is based upon and claims the benefit of priority of the prior Japanese Patent Application No. 2022-179636, filed on Nov. 9, 2022, the entire contents of which are incorporated herein by reference.

### BACKGROUND OF THE INVENTION

### 1. Field of the Invention

The embodiments discussed herein relate to a bonding material application apparatus and a bonding material application method.

### 2. Background of the Related Art

An insulated circuit substrate that is included in a semiconductor device may warp. When a bonding material is applied to the insulated circuit substrate, the insulated circuit substrate is placed on the stage of a base (pedestal) and is sucked through suction holes formed on the stage of the base, and then screen printing using a mask is performed on the insulated circuit substrate corrected to be flat by the suction (see, for example, Japanese Laid-open Patent Publication No. 2004-090137).

For such correction, for example, a retracting unit is provided that retracts a correction member to a position lower than the height position of the upper surface of a substrate held on a stage after the substrate corrected by the correction member is held on the stage and before a detection unit that detects the surface condition of the upper surface of the substrate starts to move. This prevents interference between the correction member and the detection unit that moves along the upper surface of the stage (see, for example, Japanese Laid-open Patent Publication No. 2020-136480).

As another example, a substrate placed on a table surface is sucked and fixed onto the table surface by negative pressure, so that the warpage of the substrate in a state of being sucked and fixed is reduced stably (see, for example, Japanese Laid-open Patent Publication No. 2006-286815).

In addition, the size of a substrate to be fixed onto a substrate mounting table by suction is identified by reading the barcode printed on the substrate, and then a sheet part having a perforated region is selected according to the size. By doing so, it is possible to prevent decompression suction through suction holes located outside the perforated region of the sheet part (see, for example, Japanese Laid-open Patent Publication No. 2004-322254). However, even if an insulated circuit substrate placed on the stage of a base is corrected to be flat by suction, the insulated circuit substrate does not become completely flat. This makes it difficult to apply a bonding material to a predetermined application region of the insulated circuit substrate properly.

### SUMMARY OF THE INVENTION

According to one aspect, there is provided a bonding material application apparatus that applies a bonding material to a target member while fixing the target member by applying suction thereto. The bonding material application apparatus includes: a base having a stage region at a front side thereof, and a plurality of suction holes in the stage region; an elastic member provided in the stage region, the elastic member having a plurality of through holes, each through hole being disposed at a position immediately above a corresponding one of the plurality of suction holes when viewed from a suction direction from the front side of the base to a rear side of the base; and a suction unit configured to apply the suction for suctioning the target member to be placed in the stage region in the suction direction through suction holes among the plurality of suction holes, which are respectively disposed at positions immediately below respective ones of the plurality of through holes, thereby to fix the target member to the stage region by the suction via the elastic member.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of the front surface of a semiconductor module according to a first embodiment;

FIG. 2 is a side sectional view of the semiconductor module according to the first embodiment;

FIG. 3 is a plan view of the front surface of a semiconductor unit according to the first embodiment;

FIG. 4 is a plan view of the front surface of an insulated circuit substrate according to the first embodiment;

FIG. 5 is a flowchart illustrating a semiconductor module manufacturing method according to the first embodiment;

FIG. 6 is a flowchart illustrating a semiconductor unit assembly step according to the first embodiment;

FIG. 7 is a perspective view of a bonding material application apparatus according to the first embodiment;

FIG. 8 is a plan view of the front surface of a base according to the first embodiment;

FIG. 9 is a side sectional view of the base according to the first embodiment;

FIG. 10 is a plan view illustrating an elastic sheet setting step of the semiconductor unit assembly step according to the first embodiment;

FIG. 11 is a side sectional view illustrating the elastic sheet setting step of the semiconductor unit assembly step according to the first embodiment;

FIG. 12 is a plan view illustrating an insulated circuit substrate setting step of the semiconductor unit assembly step according to the first embodiment;

FIG. 13 is a side sectional view illustrating the insulated circuit substrate setting step of the semiconductor unit assembly step according to the first embodiment;

FIG. 14 is a side sectional view illustrating a suction start step and pressing step of the semiconductor unit assembly step according to the first embodiment;

FIG. 15 is a plan view illustrating a mask setting step of the semiconductor unit assembly step according to the first embodiment;

FIG. 16 is a side sectional view illustrating the mask setting step of the semiconductor unit assembly step according to the first embodiment;

FIG. 17 is a first plan view illustrating an application step of the semiconductor unit assembly step according to the first embodiment;

FIG. 18 is a first side sectional view illustrating the application step of the semiconductor unit assembly step according to the first embodiment;

FIG. 19 is a second plan view illustrating the application step of the semiconductor unit assembly step according to the first embodiment;

FIG. 20 is a second side sectional view illustrating the application step of the semiconductor unit assembly step according to the first embodiment;

FIG. 21 is a plan view illustrating a mask removal step and suction stop step of the semiconductor unit assembly step according to the first embodiment;

FIG. 22 is a side sectional view illustrating the mask removal step and suction stop step of the semiconductor unit assembly step according to the first embodiment;

FIG. 23 is a first side sectional view illustrating an application step of a semiconductor unit assembly step according to a first reference example;

FIG. 24 is a second side sectional view illustrating the application step of the semiconductor unit assembly step according to the first reference example;

FIG. 25 is a side sectional view illustrating a mask removal step and suction stop step of the semiconductor unit assembly step according to the first reference example;

FIG. 26 is a plan view illustrating an elastic sheet setting step of a semiconductor unit assembly step according to a second reference example;

FIG. 27 is a side sectional view illustrating the elastic sheet setting step of the semiconductor unit assembly step according to the second reference example;

FIG. 28 is a side sectional view illustrating an insulated circuit substrate setting step of the semiconductor unit assembly step according to the second reference example;

FIG. 29 is a plan view illustrating a different elastic sheet that is used in the semiconductor unit assembly step according to the first embodiment;

FIG. 30 is a side sectional view illustrating the different elastic sheet that is used in the semiconductor unit assembly step according to the first embodiment;

FIG. 31 is a flowchart illustrating a semiconductor unit assembly step according to a second embodiment;

FIG. 32 is a plan view of the front surface of a base according to the second embodiment;

FIG. 33 is a side sectional view of the base according to the second embodiment;

FIG. 34 is a plan view illustrating an elastic sheet setting step of the semiconductor unit assembly step according to the second embodiment;

FIG. 35 is a side sectional view illustrating the elastic sheet setting step of the semiconductor unit assembly step according to the second embodiment;

FIG. 36 is a plan view illustrating an insulated circuit substrate setting step and suction start step of the semiconductor unit assembly step according to the second embodiment;

FIG. 37 is a side sectional view illustrating the insulated circuit substrate setting step and suction start step of the semiconductor unit assembly step according to the second embodiment; and

FIG. 38 is a side sectional view illustrating an application step of the semiconductor unit assembly step according to the second embodiment.

### DETAILED DESCRIPTION OF THE INVENTION

Hereinafter, embodiments will be described with reference to the accompanying drawings. In the following description, the terms “front surface” and “upper surface” refer to an X-Y surface facing up (in the +Z direction) in a semiconductor module 1 of drawings. Similarly, the term “up” refers to an upward direction (the +Z direction) in the semiconductor module 1 of the drawings. The terms “rear surface” and “lower surface” refer to an X-Y surface facing down (in the −Z direction) in the semiconductor module 1 of the drawings. Similarly, the term “down” refers to a downward direction (the −Z direction) in the semiconductor module 1 of the drawings. The same directionality applies to other drawings, as appropriate. The term “being located higher” refers to a state of being located on the upper side (on the +Z side) of the semiconductor module 1 of the drawings. Similarly, the term “being located lower” refers to a state of being located on the lower side (on the −Z side) of the semiconductor module 1 of the drawings. The terms “front surface,” “upper surface,” “up,” “rear surface,” “lower surface,” “down,” and “side surface” are used for convenience to describe relative positional relationships, and do not limit the technical ideas of the embodiment. For example, the terms “up” and “down” are not always related to the vertical directions to the ground. That is, the “up” and “down” directions are not limited to the gravity direction. In addition, in the following description, the term “main component” refers to a component contained in 70 wt % or more.

### First Embodiment

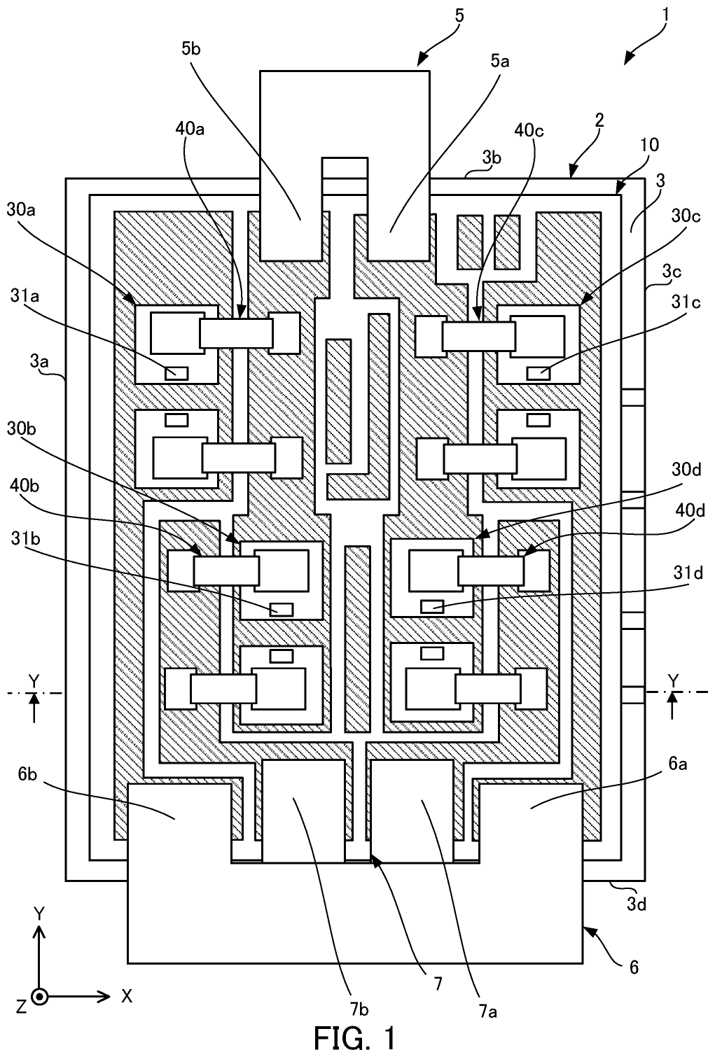

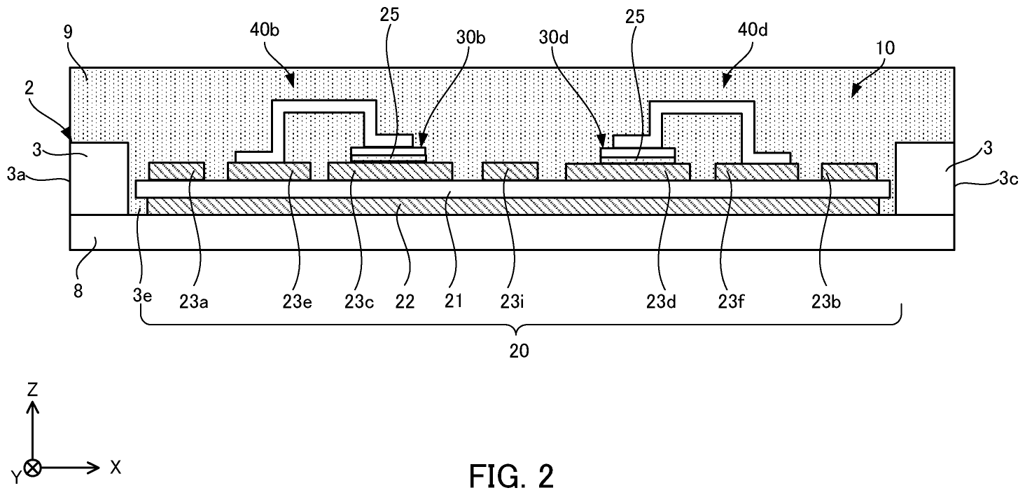

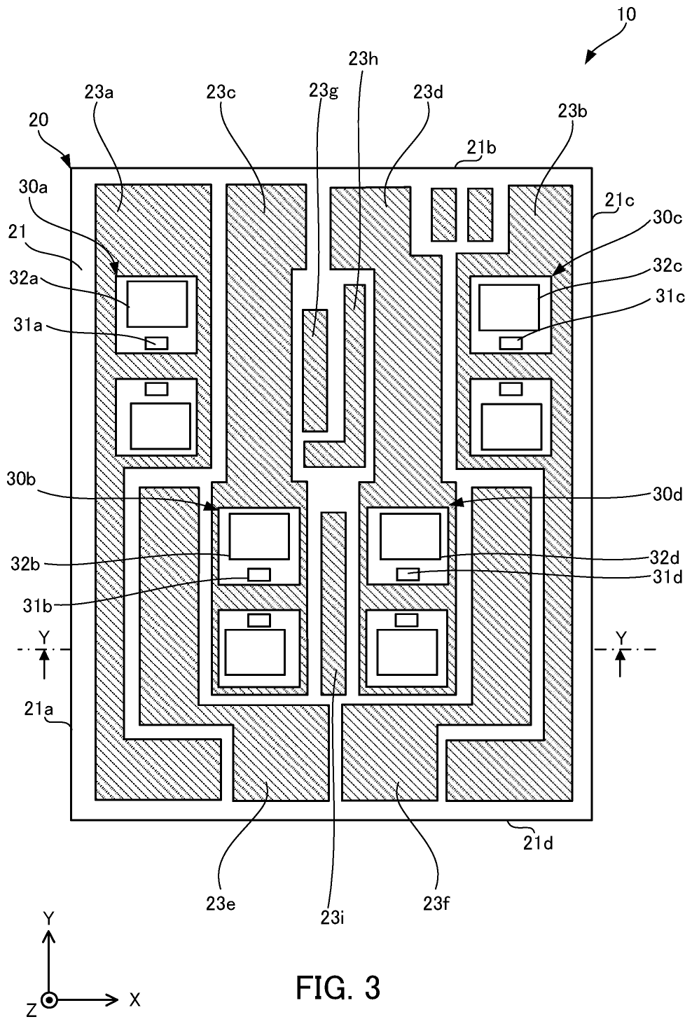

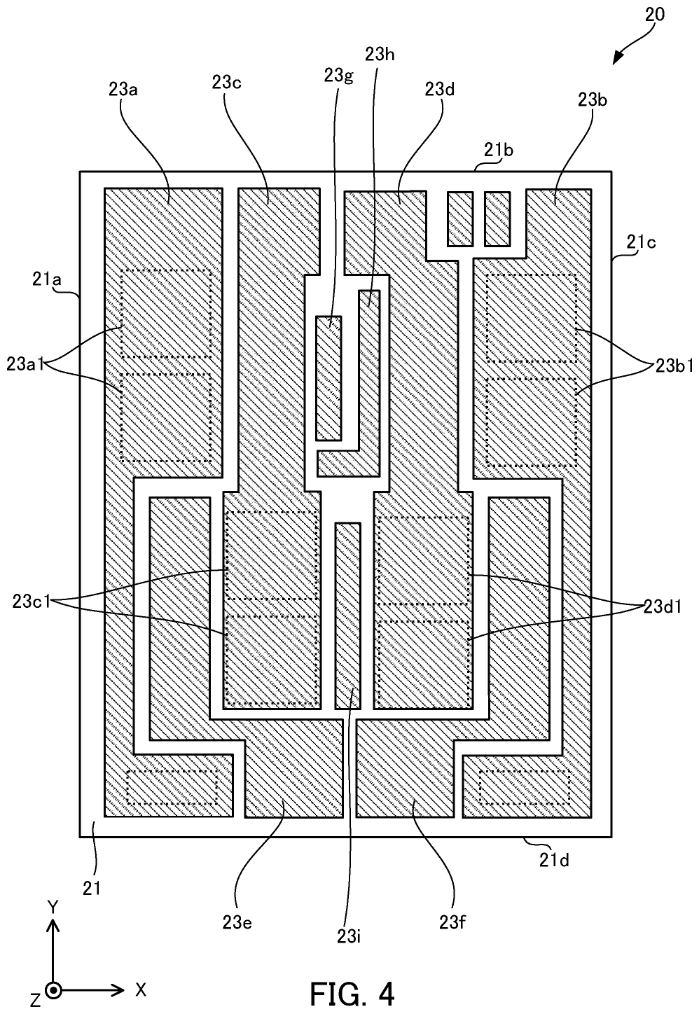

A semiconductor module according to a first embodiment will be described with reference to FIGS. 1 to 4. FIG. 1 is a plan view of the front surface of the semiconductor module according to the first embodiment. FIG. 2 is a side sectional view of the semiconductor module according to the first embodiment. FIG. 3 is a plan view of the front surface of a semiconductor unit according to the first embodiment. FIG. 4 is a plan view of the front surface of an insulated circuit substrate according to the first embodiment. In this connection, the illustration of a sealing member 9 in the semiconductor module 1 is omitted in FIG. 1. FIG. 2 is a sectional view taken along the dashed-dotted line Y-Y of FIG. 1. FIG. 4 is a plan view of an insulated circuit substrate 20 of FIG. 3 except semiconductor chips 30a to 30d.

For example, a semiconductor device may include an equivalent circuit forming an inverter circuit. Such a semiconductor device includes a plurality of individual semiconductor modules 1. For example, in the semiconductor device, three semiconductor modules 1 are arranged in order of U phase, V phase, and W phase in the X direction.

Each semiconductor module 1 includes a semiconductor unit 10, a base board 8 on which the semiconductor unit 10 is disposed, and a case 2 disposed on the base board 8 so as to accommodate the semiconductor unit 10. In addition, the semiconductor module 1 includes a sealing member 9 that fills the inside of the case 2 to seal the semiconductor unit 10.

The case 2 includes an outer frame 3, an output terminal 5, a positive electrode terminal 6, and a negative electrode terminal 7. The outer frame 3 is substantially rectangular in plan view, and has a pair of long side walls 3a and 3c and a pair of short side walls 3b and 3d. The outer frame 3 has a housing space 3e surrounded on its four sides by the pair of long side walls 3a and 3c and the pair of short side walls 3b and 3d. The housing space 3e accommodates the semiconductor unit 10 therein and is filled with the sealing member 9.

The output terminal 5 is provided at the short side wall 3b of the outer frame 3. The output terminal 5 has a U-shape in plan view. More specifically, the output terminal 5 is divided into two branches, each having an inner bonding portion 5a, 5b at the tip. The inner bonding portions 5a and 5b of the output terminal 5 are directly connected to circuit patterns 23d and 23c, respectively.

The positive electrode terminal 6 and negative electrode terminal 7 that serve as input terminals are provided at the short side wall 3d so as to face the output terminal 5 with the housing space 3e therebetween. The positive electrode terminal 6 has a U-shape in plan view. More specifically, the positive electrode terminal 6 is divided into two branches, each having an inner bonding portion 6a, 6b at the tip. The inner bonding portions 6a and 6b of the positive electrode terminal 6 are directly connected to circuit patterns 23b and 23a, respectively. The negative electrode terminal 7 has a U-shape in plan view. More specifically, the negative electrode terminal 7 is divided into two branches, each having an inner bonding portion 7a, 7b at the tip. The inner bonding portions 7a and 7b of the negative electrode terminal 7 are directly connected to circuit patterns 23f and 23e, respectively.

The inner bonding portions 5a, 6a, 7a, 5b, 6b, and 7b may be bonded to the circuit patterns 23a to 23f, using a bonding material 25 or by ultrasonic bonding. The bonding material 25 may be a solder or a sintered material. As the solder, a lead-free solder is used. The lead-free solder contains, as a main component, an alloy containing at least two of tin, silver, copper, zinc, antimony, indium, and bismuth, for example. The solder may also contain an additive. Examples of the additive include nickel, germanium, cobalt, and silicon. The solder containing the additive exhibits improved wettability, gloss, and bonding strength, which results in improving the reliability. As the sintered material, a metal material containing silver, copper, or an alloy containing at least one of these is used, for example.

Since the inner bonding portions 5a, 6a, 7a, 5b, 6b, and 7b are bonded in this manner, the output terminal 5, positive electrode terminal 6, and negative electrode terminal 7 are electrically connected to the semiconductor chips 30a to 30d of the semiconductor unit 10 accommodated in the housing space 3e. More specifically, the positive electrode terminal 6 (inner bonding portions 6a and 6b) is electrically connected to the input electrodes of the semiconductor chips 30c and 30a via the circuit patterns 23b and 23a, respectively.

The negative electrode terminal 7 (inner bonding portions 7a and 7b) is electrically connected to the output electrodes 32d and 32b of the semiconductor chips 30d and 30b via the circuit patterns 23f and 23e and lead frames 40d and 40b, respectively.

The output terminal 5 (inner bonding portions 5a and 5b) is electrically connected to the input electrodes of the semiconductor chips 30d and 30b via the circuit patterns 23d and 23c, respectively. In addition, the output terminal (inner bonding portions 5a and 5b) is electrically connected to the output electrodes 32c and 32a of the semiconductor chips 30c and 30a via the circuit patterns 23d and 23c and lead frames 40c and 40a, respectively.

Furthermore, the output terminal 5, positive electrode terminal 6, and negative electrode terminal 7 are made of a material with high electrical conductivity. Examples of the material here include copper, aluminum, and an alloy containing at least one of these. Plating may be performed on the surfaces of the output terminal 5, positive electrode terminal 6, and negative electrode terminal 7 in order to improve their corrosion resistance. Examples of the plating material here include nickel, a nickel-phosphorus alloy, and a nickel-boron alloy.

The sealing member 9 seals the semiconductor unit accommodated in the housing space 3e. The sealing member 9 may be a thermosetting resin. Examples of the thermosetting resin include an epoxy resin, a phenolic resin, a maleimide resin, and a polyester resin. The epoxy resin is preferred. Furthermore, the sealing member 9 may contain a filler. The filler is made of ceramics with both insulation property and high thermal conductivity. Examples of the filler include silicon oxide, aluminum oxide, boron nitride, and aluminum nitride.

The base board 8 has a flat plate shape, and is rectangular in plan view. In addition, the base board 8 may cover the housing space 3e of the case 2 (outer frame 3) from the bottom of the housing space 3e in plan view. This base board 8 is made of a metal with high thermal conductivity. Examples of the material here include aluminum, iron, silver, copper, and an alloy containing at least one of these. An example of the alloy is a metal composite material. Examples of the metal composite material include aluminum-silicon carbide (Al—SiC) and magnesium-silicon carbide (Mg—SiC). Plating using a plating material may be performed on the surface of the base board 8 in order to improve its corrosion resistance. Examples of the plating material include nickel and a nickel alloy.

Furthermore, a cooling unit (not illustrated) may be attached to the rear surface of the base board 8. For example, the cooling unit may be made of a metal with high thermal conductivity. The metal may be aluminum, iron, silver, copper, or an alloy containing at least one of these. In addition, the cooling unit may be a heat sink with one or more fins, a water-cooling jacket, or another. The base board 8 may be integrally formed with the cooling unit.

The semiconductor unit 10 includes an insulated circuit substrate 20, semiconductor chips 30a to 30d, and lead frames 40a to 40d. The insulated circuit substrate 20 is rectangular in plan view. The insulated circuit substrate includes an insulating plate 21, a wiring layer formed on the front surface of the insulating plate 21, and a metal plate 22 formed on the rear surface of the insulating plate 21. The wiring layer includes a plurality of circuit patterns 23a to 23i, for example. In plan view, the outer shape of the plurality of circuit patterns 23a to 23i and the outer shape of the metal plate 22 are smaller than the outer shape of the insulating plate 21 and are formed inside the insulating plate 21. In this connection, the shapes, quantity, and sizes of the plurality of circuit patterns 23a to 23i are illustrated just as an example.

The insulating plate 21 is rectangular in plan view. In addition, the corners of the insulating plate 21 may be chamfered. For example, the corners may be chamfered or rounded. The insulating plate 21 is surrounded on its four sides by a long side 21a, a short side 21b, a long side 21c, and a short side 21d, which form the outer periphery. This insulating plate 21 is made of ceramics with high thermal conductivity. The ceramics may include, for example, aluminum oxide, aluminum nitride, or silicon nitride as a main component. Furthermore, the thickness of the insulating plate 21 is in the range of 0.2 mm to 0.5 mm, inclusive, for example.

The metal plate 22 is rectangular in plan view. The corners of the metal plate 22 may be chamfered or rounded, for example. The metal plate 22 is smaller in size than the insulating plate 21 and is formed on the entire rear surface of the insulating plate 21 except the edge portion thereof. The metal plate 22 is made of a metal with high thermal conductivity as a main component. Examples of the metal here include copper, aluminum, and an alloy containing at least one of these. In addition, the thickness of the metal plate 22 is in the range of 0.1 mm to 1.5 mm, inclusive, for example. Plating may be performed on the metal plate in order to improve its corrosion resistance. Examples of the plating material here include nickel, a nickel-phosphorus alloy, and a nickel-boron alloy.

The circuit patterns 23a to 23i are formed on the entire surface of the insulating plate 21 except the edge portion thereof. Preferably, in plan view, the edge portions of the circuit patterns 23a to 23i that face the outer periphery of the insulating plate 21 overlap the edge portion of the metal plate 22 that faces the outer periphery of the insulating plate 21. As a result, the insulated circuit substrate 20 maintains the stress balance between the circuit patterns 23a to 23i and the metal plate 22 on the rear surface of the insulating plate 21. This prevents excessive warping and damage such as cracking of the insulating plate 21.

In this connection, the regions indicated by broken lines in the circuit pattern 23a are the chip regions 23a1 of two semiconductor chips 30a. The regions indicated by broken lines in the circuit pattern 23b are the chip regions 23b1 of two semiconductor chips 30c. The regions indicated by broken lines in the circuit pattern 23c are the chip regions 23c1 of two semiconductor chips 30b. The regions indicated by broken lines in the circuit pattern 23d are the chip regions 23d1 of two semiconductor chips 30d.

For example, the thicknesses of the circuit patterns 23a to 23i are in the range of 0.1 mm to 1.5 mm, inclusive. The circuit patterns 23a to 23i are made of a metal with high electrical conductivity. Examples of the metal here include copper, aluminum, and an alloy containing at least one of these. In addition, plating may be performed on the surfaces of the circuit patterns 23a to 23i in order to improve their corrosion resistance. Examples of the plating material here include nickel, a nickel-phosphorus alloy, and a nickel-boron alloy.

The circuit pattern 23a is formed adjacent to the long side 21a of the insulating plate 21 and extends from the short side 21b to the short side 21d along the long side 21a. The circuit pattern 23b and the circuit pattern 23a are approximately line symmetrical with respect to a straight line extending in the ±Y directions. The circuit pattern 23b is formed adjacent to the long side 21c of the insulating plate 21 and extends from the short side 21b to the short side 21d along the long side 21c.

The circuit pattern 23c is located next to the +Y-side portion of the circuit pattern 23a in the +X direction, and extends from the short side 21b in the −Y direction in parallel to the long side 21a. The −Y-side end portion of the circuit pattern 23c is spaced apart from the short side 21d. The circuit pattern 23c has a recess in the middle of the side portion thereof facing the long side 21c. The circuit pattern 23d and the circuit pattern 23c are approximately line symmetrical with respect to a straight line extending in the ±Y directions. The circuit pattern 23d is located next to the +Y-side portion of the circuit pattern 23b, and extends from the short side 21b in the −Y direction in parallel to the long side 21c. The −Y-side end portion of the circuit pattern 23d is spaced apart from the short side 21d. The circuit pattern 23d has a recess in the middle of the side portion thereof facing the long side 21a. In addition, the circuit pattern 23d has a cutout at a corner thereof located closest to the short side 21b on the +X-direction side.

The circuit pattern 23e is located in a region surrounded by the −Y-side portion of the circuit pattern 23a, the short side 21d, and the circuit pattern 23c. That is, the circuit pattern 23e has an approximately L shape. The circuit pattern 23f and the circuit pattern 23e are approximately line symmetrical with respect to a straight line extending in the ±Y directions. The circuit pattern 23f is located in a region surrounded by the −Y-side portion of the circuit pattern 23b, the short side 21d, and the circuit pattern 23d. That is, the circuit pattern 23f has an approximately L shape.

The circuit pattern 23g has an I shape in plan view, is located closer to the circuit pattern 23a in a region surrounded by the recesses of the circuit patterns 23c and 23d, and extends in parallel to the long side 21a. The circuit pattern 23h has an L shape in plan view, is located closer to the circuit pattern 23b in the region surrounded by the recesses of the circuit patterns 23c and 23d, and is arranged in parallel to the long side 21c. The circuit pattern 23h is arranged so as to surround the circuit pattern 23g. The circuit pattern 23i has an I shape in plan view, and is located in parallel to the long sides 21a and 21c between the circuit patterns 23c and 23d.

As the insulated circuit substrate 20 configured as above, a direct copper bonding (DCB) substrate or an active metal brazed (AMB) substrate may be used, for example. The insulated circuit substrate 20 transfers heat generated by the semiconductor chips 30a and 30d (to be described later) through the circuit patterns 23a to 23d, the insulating plate 21, and the metal plate 22 to the rear surface of the insulated circuit substrate 20, thereby dissipating the heat.

The thickness of the insulated circuit substrate in a flat state is in the range of 0.5 mm to 3.0 mm, inclusive. In addition, the insulating plate 21, metal plate 22, and the plurality of circuit patterns 23a to 23i have different linear expansion coefficients. The stress balance between the metal plate 22 and the plurality of circuit patterns 23a to 23i with respect to the insulating plate 21 is out of balance depending on the sizes and positions of the plurality of circuit patterns 23a to 23i. Therefore, the insulated circuit substrate 20 as a single unit is warped in an upward convex shape or in a downward convex shape.

In this connection, the “upward convex shape” refers to a shape where, in the insulated circuit substrate 20, the approximately central portion of the front surface (on which the plurality of circuit patterns 23a to 23i are disposed) protrudes higher (in the +Z direction) than the outer edge portion of the front surface, and the rear surface (on which the metal plate 22 is disposed) is accordingly recessed toward the front surface (in the +Z direction). On the other hand, the “downward convex shape” refers to a shape where, in the insulated circuit substrate 20, the approximately central portion of the rear surface protrudes lower (in the −Z direction) than the outer edge portion of the rear surface, and the front surface is accordingly recessed toward the rear surface (in the −Z direction).

The semiconductor chips 30a to 30d are power devices made of silicon carbide. One example of such a power device is a power metal-oxide-semiconductor field-effect transistor (MOSFET). The semiconductor chips 30a to 30d of this type each have a drain electrode serving as an input electrode (main electrode) on the rear surface thereof and have a gate electrode serving as a control electrode 31a to 31d and a source electrode serving as an output electrode 32a to 32d (main electrode) on the front surface thereof.

Alternatively, the semiconductor chips 30a to 30d may be power devices made of silicon. One example of such a power device is a reverse conducting-insulated gate bipolar transistor (RC-IGBT). An RC-IGBT integrates an IGBT serving as a switching element and a free-wheeling diode (FWD) serving as a diode element on one chip. For example, the semiconductor chips 30a to 30d of this type each have a collector electrode serving as an input electrode (main electrode) on the rear surface thereof and have a gate electrode serving as a control electrode and an emitter electrode serving as an output electrode (main electrode) on the front surface thereof.

In this connection, the semiconductor chips 30a, 30b, 30c, and 30d are disposed in plurality on the circuit patterns 23a, 23c, 23b, and 23d, respectively, as illustrated in FIG. 1. In the first embodiment, two semiconductor chips are disposed on each of the circuit patterns 23a, 23c, 23b, and 23d. In this case, the semiconductor chips 30a to 30d adjacent to each other are disposed such that their control electrodes 31a to 31d face each other. In this connection, the semiconductor chips 30a to 30d are bonded to the circuit patterns 23a, 23c, 23b, and 23d using the bonding material 25.

The lead frames 40a to 40d electrically connect the output electrodes 32a to 32d on the front surfaces of the semiconductor chips 30a to 30d to the circuit patterns 23c, 23e, 23d, and 23f. In this connection, the lead frames 40a to 40d are bonded to the output electrodes 32a to 32d of the semiconductor chips 30a to 30d using the above-described bonding material 25. The lead frames 40a to 40d are bonded to the circuit patterns 23c, 23e, 23d, and 23f, using the above-described bonding material 25 or by ultrasonic bonding.

The lead frames 40a to 40d are made of a material with high electrical conductivity and high thermal conductivity. Examples of the material here include copper, aluminum, and an alloy containing at least one of these. In addition, plating may be performed on the surfaces of the lead frames 40a to 40d in order to improve their corrosion resistance. In this case, examples of the plating material include nickel, a nickel-phosphorus alloy, and a nickel-boron alloy.

In this connection, although this is not illustrated, the control electrodes 31a and 31c of the semiconductor chips 30a and 30c are connected to the circuit patterns 23g and 23h using wiring members, respectively. The control electrodes 31b and 31d of the semiconductor chips 30b and 30d are connected to the circuit pattern 23i using wiring members. A control signal is input from the outside to the circuit patterns 23g, 23h, and 23i.

Examples of the wiring members include lead frames and wires. The wires are made of a material with high electrical conductivity as a main component. Examples of the material here include gold, copper, aluminum, and an alloy containing at least one of these. The wires are preferably made of an aluminum alloy containing a very small amount of silicon.

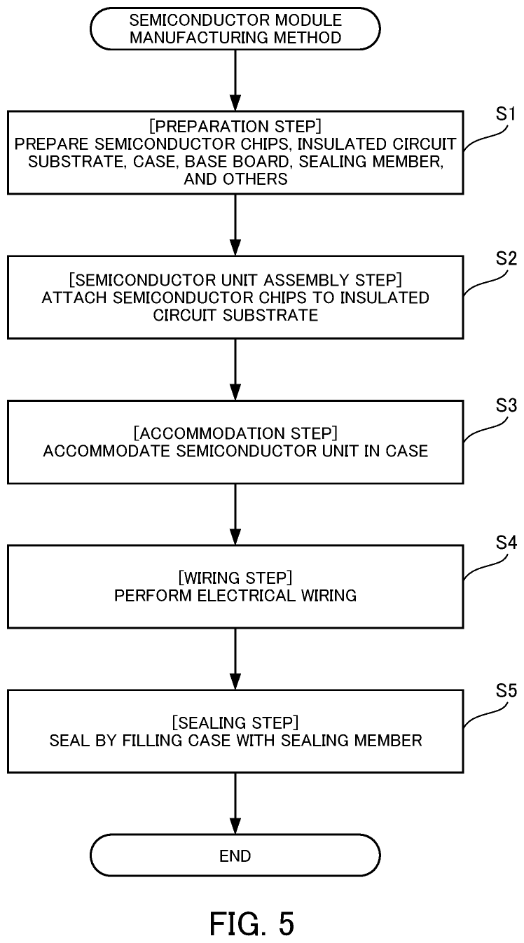

The following describes a method of manufacturing the semiconductor module 1 with reference to FIG. 5. FIG. 5 is a flowchart illustrating a semiconductor module manufacturing method according to the first embodiment. First, a preparation step of preparing the components of the semiconductor module 1 is executed (step S1). For example, the components include the semiconductor chips 30a to 30d, insulated circuit substrate 20, case 2, base board 8, and sealing member 9. In addition to these, other components needed for manufacturing the semiconductor module 1 may be prepared. Furthermore, in addition to the components, jigs and manufacturing equipment that are used for manufacturing the semiconductor module 1 may be prepared.

Then, a semiconductor unit assembly step of assembling the semiconductor unit 10 is executed (step S2). Here, a bonding material 25a (to be described later) is applied to the circuit patterns 23a to 23d of the insulated circuit substrate 20, and then the semiconductor chips 30a, 30c, 30b, and 30d are bonded. In addition, the lead frames 40a, 40c, 40b, and 40d are bonded to connect the semiconductor chips 30a, 30c, 30b, and 30d to the circuit patterns 23c, 23d, 23e, and 23f, respectively. Through this step, the semiconductor unit 10 is assembled. In this connection, the semiconductor unit assembly step will be described in detail later.

After that, an accommodation step of accommodating the semiconductor unit 10 in the case 2 is executed (step S3). The semiconductor unit 10 is bonded to a predetermined region of the base board 8 using the bonding material 25. The case 2 is attached to the outer periphery of the base board 8 using an adhesive. At this time, the semiconductor unit 10 on the base board 8 is surrounded by the case 2. Through this step, the semiconductor unit 10 is accommodated in the case 2.

Then, a wiring step of performing electrical wiring of the semiconductor unit 10 inside the case 2 is executed (step S4). Inside the case 2, the inner bonding portions 5b and 5a of the output terminal 5 are bonded respectively to the circuit patterns 23c and 23d of the insulated circuit substrate 20. The inner bonding portions 6b and 6a of the positive electrode terminal 6 are bonded respectively to the circuit patterns 23a and 23b of the insulated circuit substrate 20. The inner bonding portions 7b and 7a of the negative electrode terminal 7 are bonded respectively to the circuit patterns 23e and 23f of the insulated circuit substrate 20. In this connection, the above bonding may be done by ultrasonic bonding or using the bonding material 25. In addition, wires are bonded to connect the control electrodes 31a to 31d of the semiconductor chips 30a to 30d to the circuit patterns 23g, 23h, and 23i.

After that, a sealing step of filling the case 2 with the sealing member 9 to seal the semiconductor unit 10 is executed (step S5). The sealing member 9 is applied to fill the housing space 3e of the case 2 where the semiconductor unit 10 is accommodated. At this time, the sealing member 9 is applied to fill the housing space 3e until the sealing member 9 seals at least the semiconductor unit 10 entirely. The applied sealing member 9 is then cured. In the manner described above, the semiconductor module 1 illustrated in FIGS. 1 and 2 is manufactured.

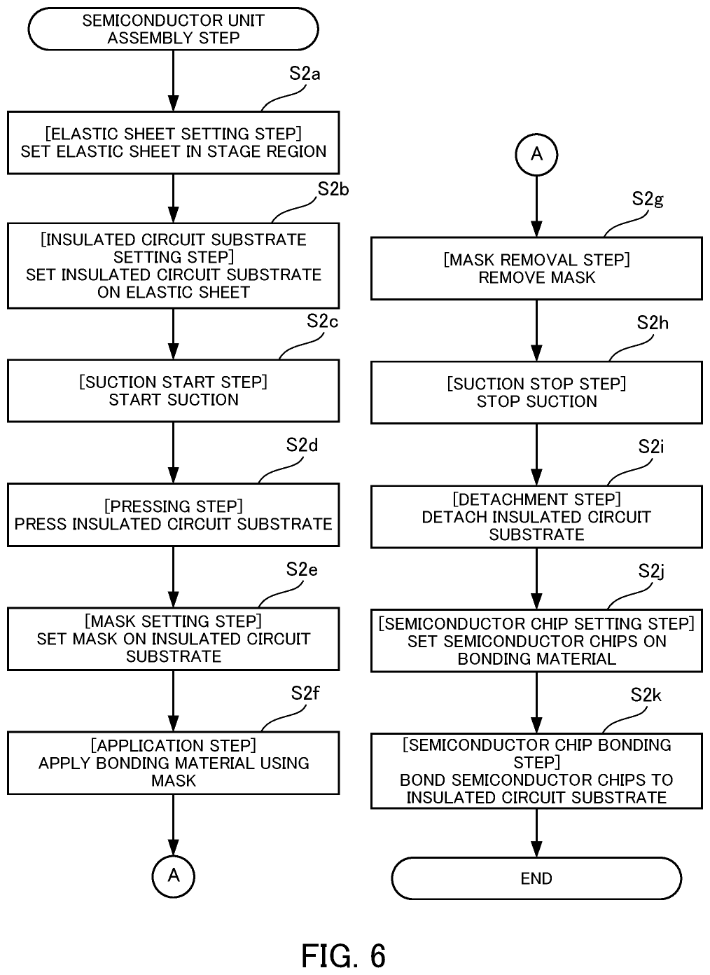

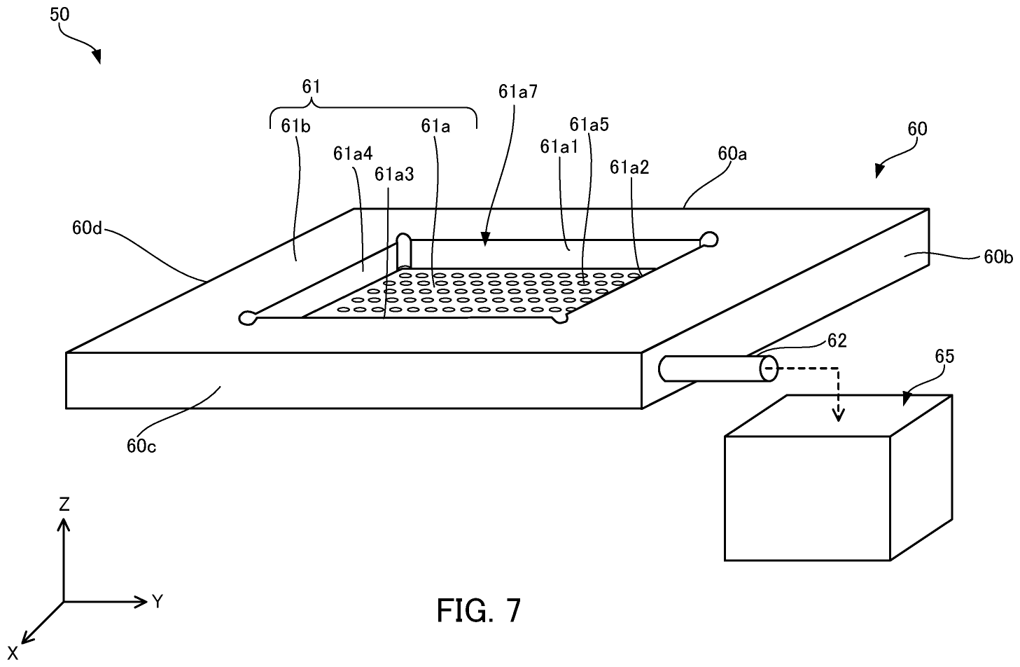

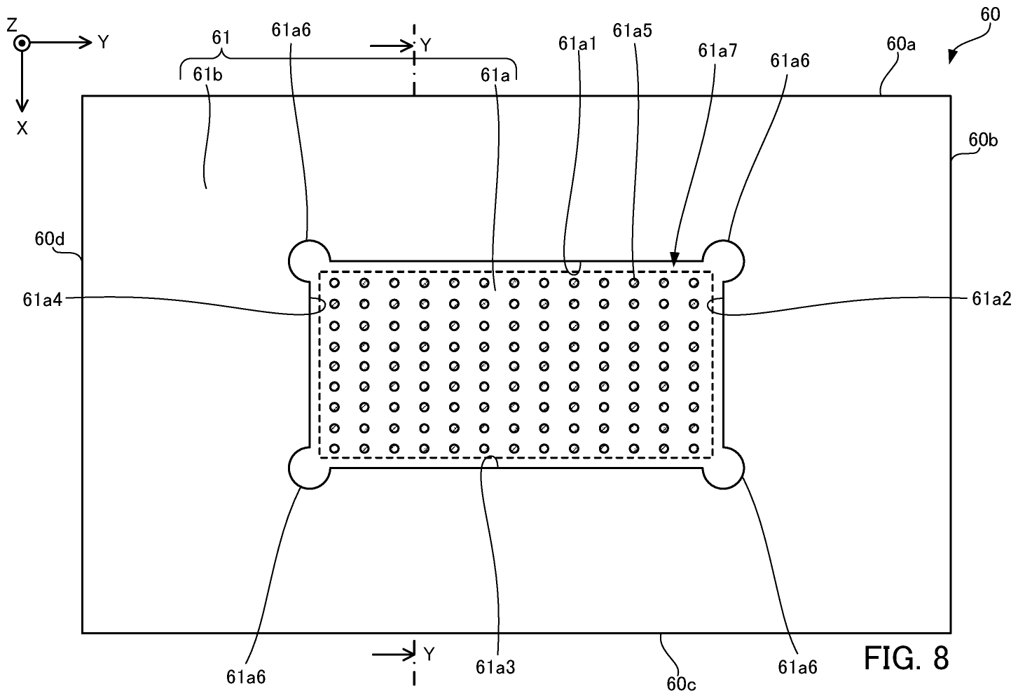

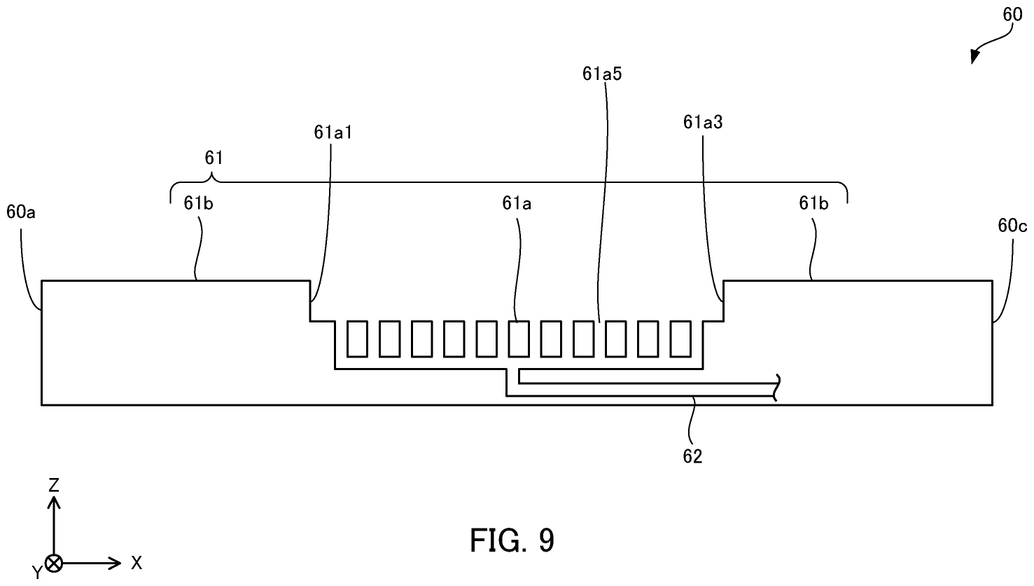

The following describes the semiconductor unit assembly step S2 with reference to FIG. 6, and then describes a base that is used in this step with reference to FIGS. 7 to 9. FIG. 6 is a flowchart illustrating the semiconductor unit assembly step according to the first embodiment. FIG. 7 is a perspective view of a bonding material application apparatus according to the first embodiment. FIG. 8 is a plan view of the front surface of the base according to the first embodiment. FIG. 9 is a side sectional view of the base according to the first embodiment. In this connection, FIG. 9 is a sectional view taken along the dashed-dotted line Y-Y of FIG. 8.

Before the description on the semiconductor unit assembly step, a bonding material application apparatus 50 will be described. As illustrated in FIG. 7, the bonding material application apparatus 50 includes a base 60, an elastic sheet 63 (to be described later), and a suction device 65. The base 60 has a flat plate shape, and has a front surface 61 and side surfaces 60a to 60d surrounding the four sides of the front surface 61 in order. In this connection, the front surface 61 is rectangular in plan view. In plan view, the side surfaces 60a and 60c correspond to the long side of the base 60 (front surface 61), and the side surfaces 60b and 60d correspond to the short side of the base 60 (front surface 61). Each side surface 60a to 60d is connected at the right angle to the front surface 61. In this connection, the base 60 only needs to have the front surface 61, and the shape thereof is not limited to the flat plate shape.

The base 60 has a stage region 61a set in the central portion of the front surface 61 thereof, and a support region 61b set outside the entire stage region 61a. In other words, the support region 61b is an area of the front surface 61 except the stage region 61a. Both the stage region 61a and the support region 61b are substantially flat.

The stage region 61a is rectangular in plan view so as to correspond to the insulated circuit substrate 20, and is approximately the same in size as the insulated circuit substrate 20. The stage region 61a is recessed in the front surface 61 such that the stage region 61a is located lower (in the −Z direction) than the support region 61b and is approximately parallel to the support region 61b. That is, the stage region 61a forms a step with the support region 61b.

A plurality of suction holes 61a5 are formed in the stage region 61a. The plurality of suction holes 61a5 are formed in an area that corresponds to the metal plate 22 of the insulated circuit substrate 20 when the insulated circuit substrate 20 is placed in the stage region 61a as described later. By doing so, it is possible to suck the metal plate 22 through the plurality of suction holes 61a5 reliably, as will be described later. In addition, the plurality of suction holes 61a5 are not clustered, but may be uniformly distributed in a grid pattern in the stage region 61a. The plurality of suction holes 61a5 do not need to be formed in a grid pattern as long as they are formed in an area that corresponds to the metal plate 22 of the insulated circuit substrate 20 when the insulated circuit substrate 20 is placed in the stage region 61a. The shape of each suction hole 61a5 in plan view may be, for example, a circular, square, or diamond shape. The sizes and quantity of the plurality of suction holes 61a5 are set to achieve reliable suction.

The four sides of the recessed stage region 61a and the support region 61b are integrally connected to inner surfaces 61a1 to 61a4. The inner surfaces 61a1 to 61a4 are each connected at approximately the right angle to the stage region 61a and the support region 61b. The inner surfaces 61a1 to 61a4 may be substantially flat. The heights (the depth of the stage region 61a from the support region 61b in the ±Z directions) of the inner surfaces 61a1 to 61a4 may be approximately equal to the total thickness of the insulated circuit substrate 20 in a flat state and elastic sheet 63 (to be described later). Surrounded by the stage region 61a and inner surfaces 61a1 to 61a4, a setting space 61a7 is formed. The size of the setting space 61a7 is set to place therein the insulated circuit substrate 20 kept flat. The front surface of the insulated circuit substrate 20 (circuit patterns 23a to 23i) kept flat, when placed in the setting space 61a7, is substantially flush with the support region 61b.

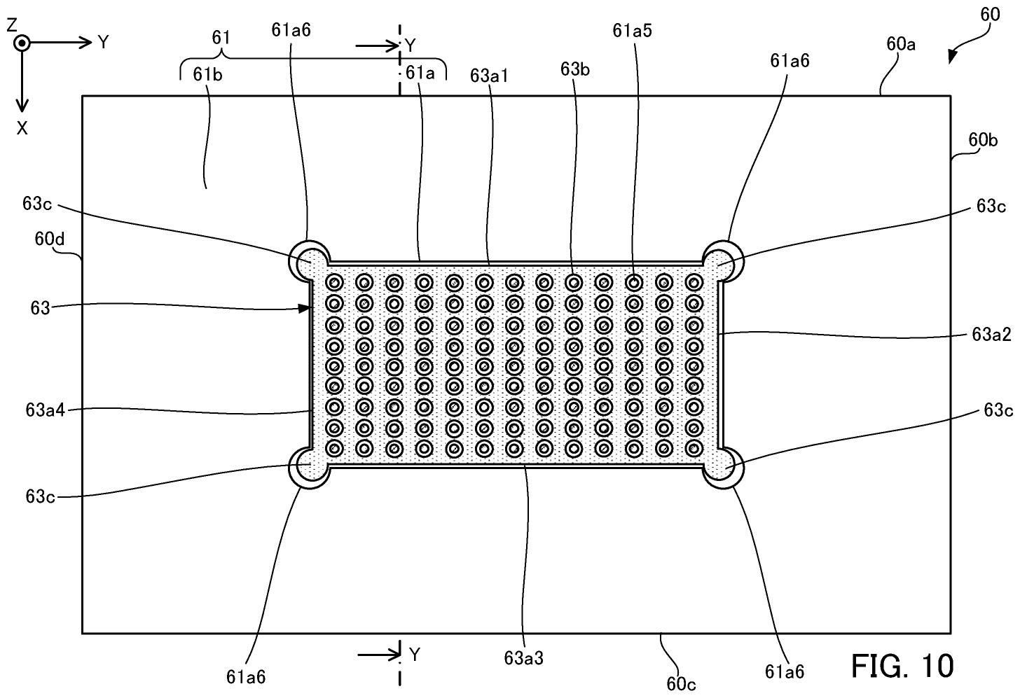

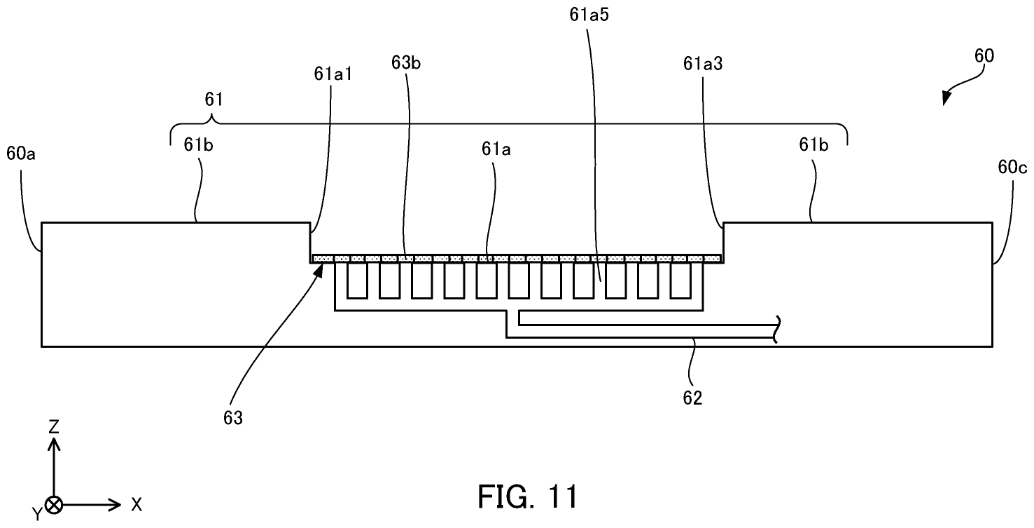

In addition, a recess 61a6 is formed at each corner of the stage region 61a. In plan view, the recess 61a6 is recessed outwardly (toward the support region 61b) from each corner of the stage region 61a. The recess 61a6 only needs to be recessed in plan view, and for example, has a circular shape. The recess 61a6 is recessed in plan view, as described now, and has a hollow extending up to the stage region 61a. Such a recess 61a6 may be formed at least one of the four corners of the stage region 61a. In the first embodiment, such recesses 61a6 are formed at all the corners of the stage region 61a, as an example. In addition, the elastic sheet 63 (see FIGS. 10 and 11) is disposed in the stage region 61a. The elastic sheet 63 will be described in detail later.

A suction pipe 62 is formed in the side surface 60b of the base 60. The suction pipe 62 extends from the side surface 60b and connects to the plurality of suction holes 61a5 inside the base 60. That is, each suction hole 61a5 and the suction pipe 62 are connected to each other so as to allow air to pass therethrough. In this connection, the attachment position of the suction pipe 62 to the base 60 illustrated in FIG. 7 is just an example. For example, the suction pipe 62 may be attached to any of the side surfaces 60a, 60c, and 60d, or alternatively may be attached to the rear surface of the base 60. Furthermore, a plurality of suction pipes 62 may be provided. Still further, the suction pipe 62 may be integrally connected to the base 60. The suction pipe 62 is connected to the suction device 65 so as to allow air to pass therethrough. In this connection, the base 60 and suction pipe 62 are preferably made of a material with a small linear expansion coefficient. One example of this material is stainless steel.

The suction device 65 produces a negative pressure to create suction from the plurality of suction holes 61a5 via the suction pipe 62 in the direction from the front surface of the stage region 61a toward the opposite side thereof. The suction device 65 controls the amount of suction per unit time. For example, the suction device 65 increases the amount of suction per unit time to increase the suction force, and also decreases the amount of suction per unit time to reduce the suction force. In addition, the suction device 65 keeps the amount of suction per unit time to create suction with a fixed suction force.

The semiconductor unit assembly step is executed using the bonding material application apparatus 50 as will be described below. First, an elastic sheet setting step of setting the elastic sheet 63 in the stage region 61a of the base 60 is executed (step S2a). The elastic sheet setting step will be described with reference to FIGS. 10 and 11. FIG. 10 is a plan view illustrating the elastic sheet setting step of the semiconductor unit assembly step according to the first embodiment. FIG. 11 is a side sectional view illustrating the elastic sheet setting step of the semiconductor unit assembly step according to the first embodiment. In this connection, FIG. 11 is a sectional view taken along the dashed-dotted line Y-Y of FIG. 10.

The elastic sheet 63 is made of a material with a predetermined elasticity as a main component and is formed in a sheet shape. Examples of this material include a silicon resin (silicone) and a fluorine resin (polytetrafluoroethylene (PTFE)). This elastic sheet 63 is rectangular in plan view and is surrounded on its four sides by sides 63a1 to 63a4 in order. In this connection, in plan view, the sides 63a1 and 63a3 correspond to the long side, whereas the sides 63a2 and 63a4 correspond to the short side. The shape and size of the elastic sheet 63 correspond to the shape and size of the stage region 61a in plan view. In addition, the thickness of the elastic sheet 63 is entirely uniform and is in the range of 50 μm to 200 μm, inclusive.

A plurality of through holes (openings) 63b are formed in the elastic sheet 63. The elastic sheet 63 is provided in the stage region 61a. Each through hole 63b is disposed at a position immediately above one of the suction holes 61a5 and has a size greater than a size of the immediately above one suction hole 61a5 such that an outer periphery of the through hole 63b surrounds an outer periphery of the immediately above one suction hole 61a5 when viewed from the Z direction. Thus, when the elastic sheet 63 is placed in the stage region 61a, the plurality of through holes 63b communicate with the plurality of suction holes 61a5 and continuously surround the outer periphery of each suction hole 61a5 in a ring shape. At this time, the plurality of through holes 63b only need to communicate with the plurality of suction holes 61a5, and the shapes and a total number of the plurality of through holes 63b do not need to be shapes and the number that correspond to those of the plurality of suction holes 61a5. Specifically, as long as the suction holes 61a5 can be disposed within respective ones of the through holes 63b when viewed from the Z direction, the shapes can differ from one another. Further, through holes 63b do not need to be formed to correspond to all of the suction holes 61a5 but necessary ones for the suction for the target member, and thus a total number of the through holes 63b can be less than a total number of the suction holes 61a5. Further, sizes of the suction holes 61a5 and the through holes 63b can differ from one another as long as the suction holes 61a5 can be disposed within respective ones of the through holes 63b when viewed from the Z direction. In this connection, the first embodiment exemplifies the case where the quantity, shapes, and sizes of the plurality of through holes 63b correspond to those of the plurality of suction holes 61a5.

In addition, in the elastic sheet 63 illustrated in FIGS. 10 and 11 in the first embodiment, the through holes 63b are formed so as to correspond to the plurality of suction holes 61a5 formed in the stage region 61a. More specifically, in this case, the number of through holes 63b in the elastic sheet 63 is equal to the number of suction holes 61a5 in the stage region 61a. However, the number of through holes 63b in the elastic sheet 63 is not limited to this case. The number of through holes 63b that are formed in the elastic sheet 63 may be set according to the position and degree of a warpage of the insulated circuit substrate 20. That is, the through holes 63b may be formed in the elastic sheet 63 according to suction holes 61a5 corresponding to a portion of the insulated circuit substrate 20 where suction is desired. The setting of the through holes 63b to be formed in the elastic sheet 63 may be determined as described above, so that the insulated circuit substrate 20 warped may be corrected to be flat efficiently. Therefore, the number of through holes 63b in the elastic sheet 63 may be equal to or less than the number of suction holes 61a5 in the stage region 61a.

In addition, as described above, the plurality of through holes 63b only need to communicate with the plurality of suction holes 61a5 and continuously surround the outer periphery of each suction hole 61a5 in a ring shape. Therefore, the plurality of through holes 63b are not limited to those formed in the elastic sheet 63. For example, a plurality of elastic sheets 63 can be disposed and the plurality of elastic sheets 63 together have the through holes 63b for the suction holes 61a5 that are necessary for the suction. Further, ring-shaped sheets made of the same material as the elastic sheet 63 may be respectively provided at the plurality of suction holes 61a5. However, one elastic sheet 63 may be easier to be set in the stage region 61a than such plurality of elastic sheets or ring-shaped sheets.

In addition, a fixing portion 63c is formed at each of the four corners of the elastic sheet 63. The fixing portion 63c is made of the same material as the elastic sheet 63 and is integrally formed with the elastic sheet 63. The fixing portion 63c only needs to be formed at least one of the four corners of the elastic sheet 63. When the elastic sheet 63 is set in the stage region 61a, the fixing portions 63c are set in the recesses 61a6. This prevents misalignment of the elastic sheet 63.

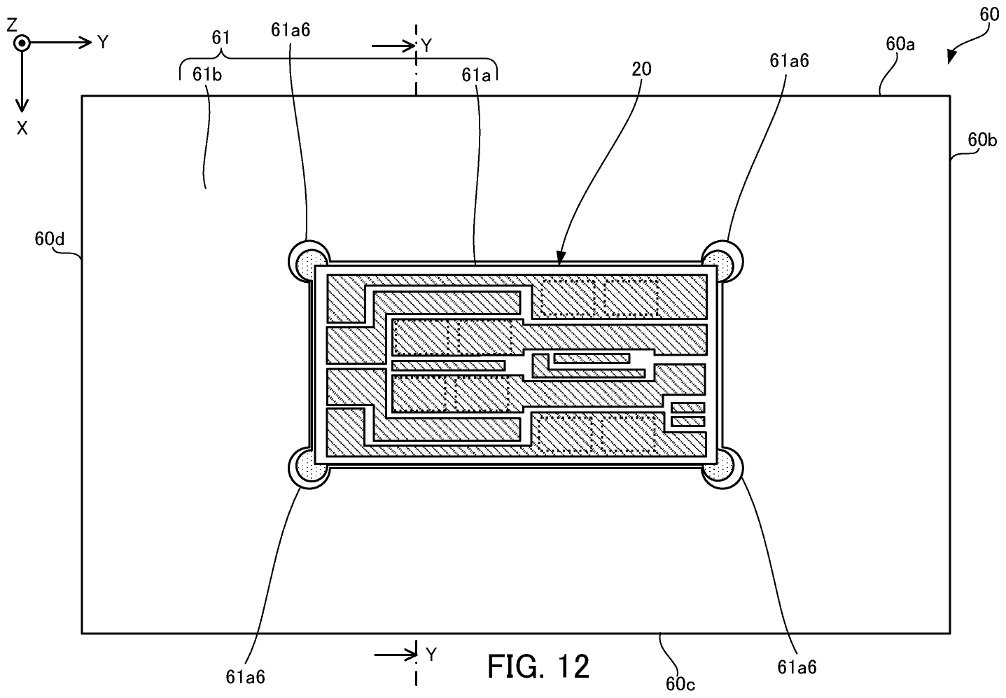

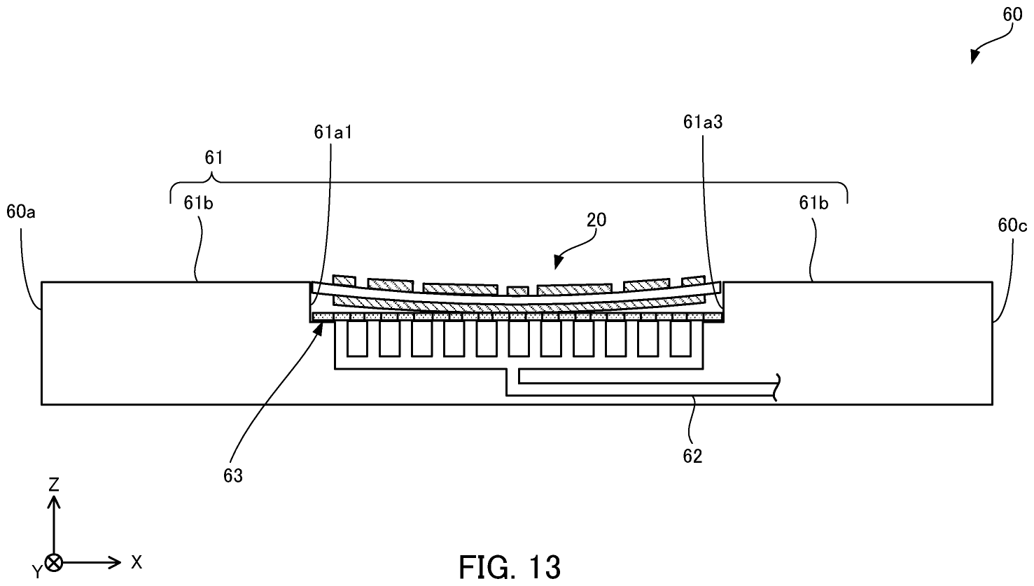

After that, an insulated circuit substrate setting step of setting the insulated circuit substrate 20 on the elastic sheet 63 is executed (step S2b). The insulated circuit substrate setting step will be described with reference to FIGS. 12 and 13. FIG. 12 is a plan view illustrating the insulated circuit substrate setting step of the semiconductor unit assembly step according to the first embodiment. FIG. 13 is a side sectional view illustrating the insulated circuit substrate setting step of the semiconductor unit assembly step according to the first embodiment. FIG. 13 is a sectional view taken along the dashed-dotted line Y-Y of FIG. 12.

The insulated circuit substrate 20 is set in the stage region 61a as illustrated in FIGS. 12 and 13. In this example, the insulated circuit substrate 20 is warped in a downward convex shape. Therefore, the central portion of the rear surface of the insulated circuit substrate 20 directly contacts the stage region 61a, but the outer edge portion of the rear surface of the insulated circuit substrate 20 is located above the stage region 61a with a gap therebetween. That is, the outer edge portion of the front surface of this insulated circuit substrate 20 (circuit patterns 23a to 23i) is located higher (in the +Z direction) than the support region 61b of the base 60.

Then, a suction start step of starting suction is executed (step S2c). The suction device 65 is driven to start to suck the insulated circuit substrate 20 from the plurality of suction holes 61a5 via the plurality of through holes 63b formed in the elastic sheet 63. When the amount of suction per unit time has reached a predetermined value after the start of the suction, the suction device 65 keeps the amount of suction. By sucking the insulated circuit substrate 20 warped in an upward convex shape or a downward convex shape, the rear surface of the insulated circuit substrate 20 is drawn toward the stage region 61a, so that the insulated circuit substrate 20 closely adheres to the elastic sheet 63 set in the stage region 61a without any gap therebetween.

When the insulated circuit substrate 20 warped in an upward convex shape is sucked, the central portion of the rear surface of the insulated circuit substrate 20 is drawn toward the stage region 61a, which causes the entire rear surface of the insulated circuit substrate 20 to closely adhere to the elastic sheet 63 set in the stage region 61a. As a result, the insulated circuit substrate 20 is made flat. However, in the case of the insulated circuit substrate 20 warped in an upward convex shape, the gap between the insulated circuit substrate 20 and the stage region 61a may be reduced, but the reduction may be insufficient to make the insulated circuit substrate 20 flat depending on the degree of the warpage and the suction force.

On the other hand, when the insulated circuit substrate 20 warped in a downward convex shape is sucked, the outer edge portion of the rear surface of the insulated circuit substrate 20 is drawn toward the stage region 61a, which reduces the gap between the insulated circuit substrate 20 and the elastic sheet 63 set in the stage region 61a. However, in most cases, the insulated circuit substrate fails to closely adhere to the elastic sheet 63. Although the warpage of the insulated circuit substrate 20 is reduced, the insulated circuit substrate 20 is still in a downward convex shape. In this connection, even the insulated circuit substrate 20 warped in a downward convex shape may be made flat, depending on the degree of the warpage and the suction force.

In the first embodiment, the description is made on the example where there is a gap between the insulated circuit substrate 20 being sucked and the stage region 61a, irrespective of whether the insulated circuit substrate 20 is warped in an upward convex shape or in a downward convex shape.

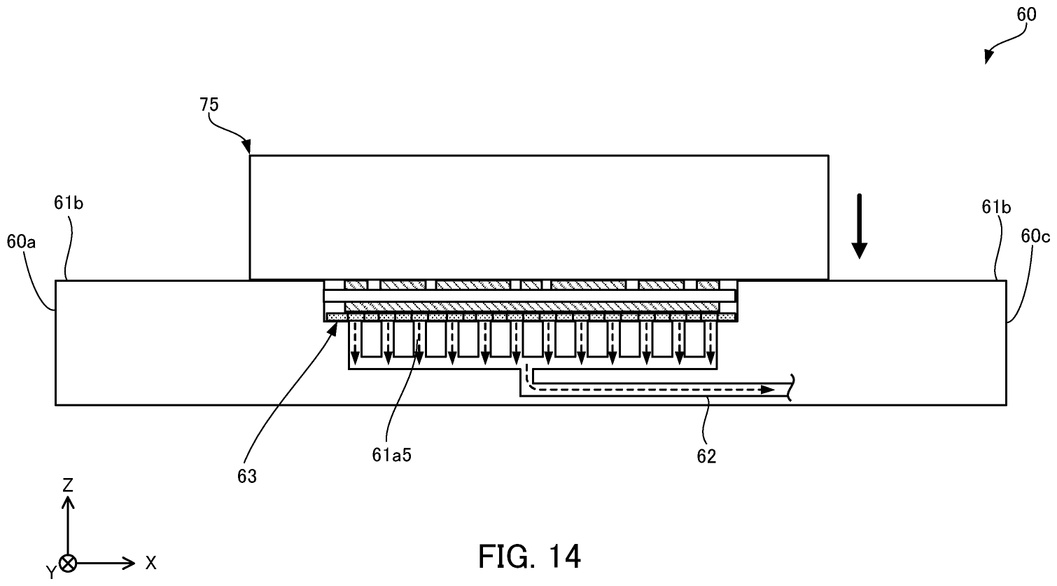

Then, a pressing step of pressing the front sur face of the insulated circuit substrate 20 toward the stage region 61a is executed (step S2d) while the insulated circuit substrate 20 is sucked. The pressing step will be described with reference to FIG. 14. FIG. 14 is a side sectional view illustrating the suction start step and pressing step of the semiconductor unit assembly step according to the first embodiment. In this connection, FIG. 14 corresponds to the sectional view of FIG. 13.

Here, a weight 75 is placed on the front surface of the insulated circuit substrate 20 so as to press the insulated circuit substrate 20 toward the stage region 61a. The weight 75 is longer than the stage region 61a in plan view. That is, the weight 75 extends over the stage region 61a up to the support region 61b located on opposite sides of the stage region 61a. Since the weight 75 is supported by the support region 61b, the weight 75 presses the insulated circuit substrate 20 toward the stage region 61a but does not press the insulated circuit substrate 20 too much. This in turn prevents the insulated circuit substrate from being damaged due to the pressing. The pressing causes the entire rear surface of the insulated circuit substrate 20 to closely adhere to the elastic sheet 63. Once the insulated circuit substrate 20 closely adheres to the elastic sheet 63, the suction via the plurality of through holes 63b keeps the insulated circuit substrate 20 flat. Especially, since the outer periphery of each suction hole 61a5 in the stage region 61a is continuously surrounded in a ring shape by the elastic sheet 63, the insulated circuit substrate 20 is sucked from the plurality of suction holes 61a5 reliably without generating any undesirable suction paths from the plurality of suction holes 61a5. Therefore, even if the weight 75 is removed, the insulated circuit substrate 20 is kept flat. At this time, the front surface of the insulated circuit substrate 20 in the flat state is flush with the support region 61b.

In this connection, the use of the weight 75 for the pressing is just an example. For example, a plunger whose pressing force is adjusted may be used to press the front surface of the insulated circuit substrate 20 toward the stage region 61a. In addition, the shape of the weight 75 is not limited to the block shape illustrated in FIG. 14, as long as the weight 75 includes a pressing surface to press the insulated circuit substrate 20.

In this connection, the suction start step S2c and the pressing step S2d may be executed in reverse order. That is, after the insulated circuit substrate setting step, the weight 75 is placed on the front surface of the insulated circuit substrate 20. Then, the suction starts while the insulated circuit substrate 20 is pressed toward to the stage region 61a. Even in this order of execution, the insulated circuit substrate 20 is caused to closely adhere to the elastic sheet 63 and is kept flat.

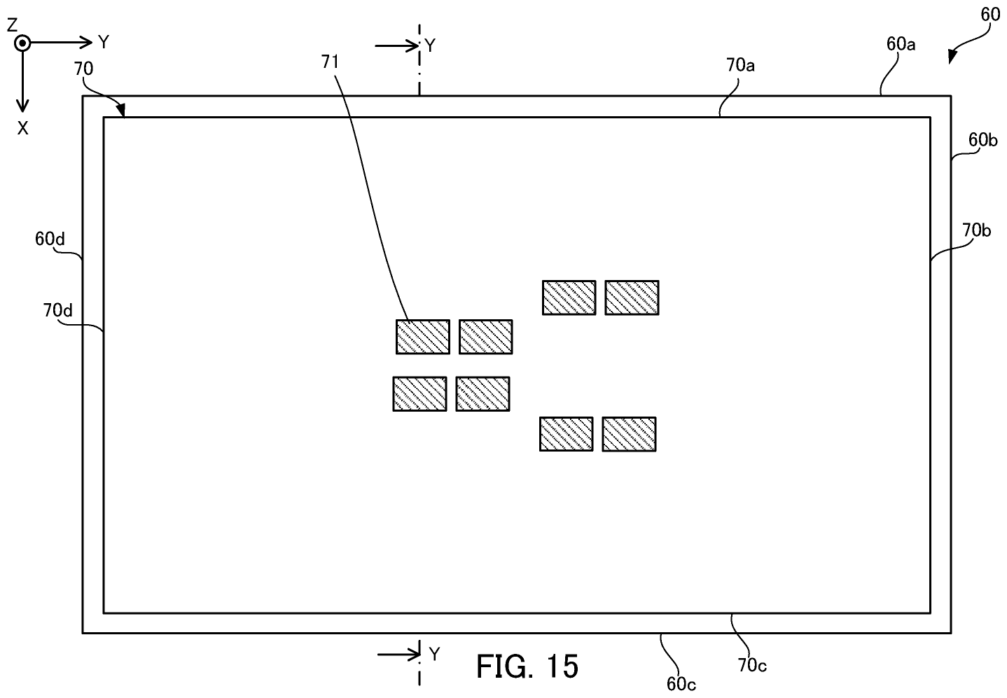

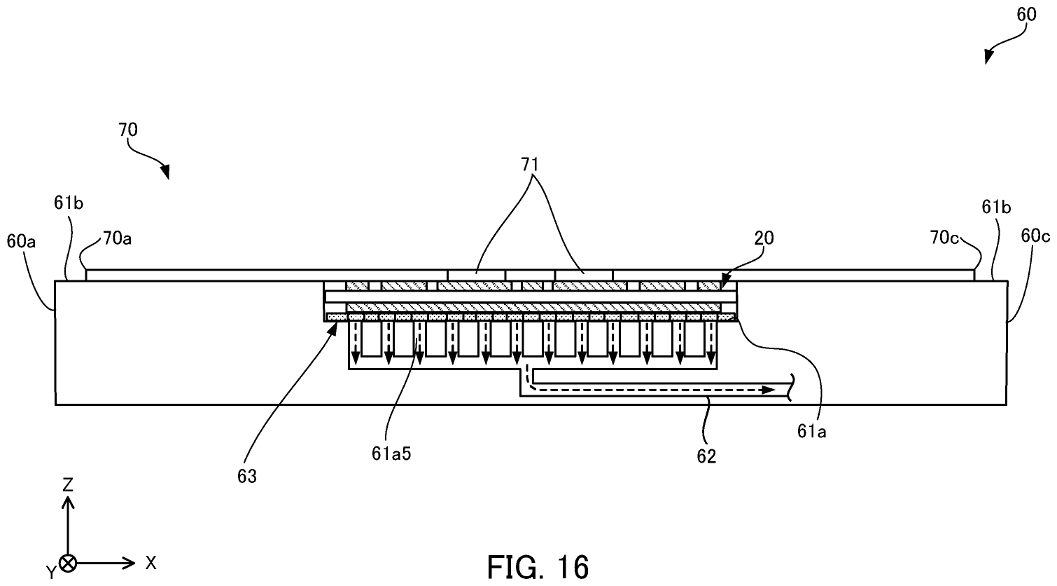

Then, a mask setting step of setting a mask on the front surface of the insulated circuit substrate 20 kept flat is executed (step S2e). The mask setting step will be described with reference to FIGS. 15 and 16. FIG. 15 is a plan view illustrating the mask setting step of the semiconductor unit assembly step according to the first embodiment. FIG. 16 is a side sectional view illustrating the mask setting step of the semiconductor unit assembly step according to the first embodiment. In this connection, FIG. 16 is a sectional view taken along the dashed-dotted line Y-Y of FIG. 15.

A mask 70 is set on the front surface 61 of the base 60. The mask 70 is rectangular in plan view and is surrounded on its four sides by sides 70a to 70d. Transfer openings 71 are formed in the mask 70 so that, when the mask 70 is set on the base 60, the transfer openings 71 correspond to application regions of the insulated circuit substrate 20 where the bonding material 25 is to be applied. When the mask 70 is placed on the front surface 61 (support region 61b) of the base 60, the mask 70 covers the front surface 61 (support region 61b) except the outer edge thereof. The mask 70 is in direct contact with the front surface of the insulated circuit substrate 20 and the support region 61b. As with the base 60, the mask 70 is preferably made of a material with a low linear expansion coefficient. One example of this material is stainless steel. In addition, the thickness of the mask 70 corresponds to a desired thickness of the bonding material 25 and is, for example, in the range of 50 μm to 200 μm, inclusive.

In this connection, the above-described pressing step S2d needs to be executed before the mask setting step S2e. That is, the insulated circuit substrate 20 is not pressed via the mask 70. This is because pressing the insulated circuit substrate 20 via the mask 70 may damage the mask 70.

In addition, the mask setting step S2e may be executed after the insulated circuit substrate setting step S2b and before the suction start step S2c. In this case, the pressing step S2d is not executed because, as described above, there needs to avoid pressing the mask 70. That is, after the elastic sheet setting step S2a is executed, the insulated circuit substrate setting step S2b, the mask setting step S2e, and the suction start step S2c may be executed in this order.

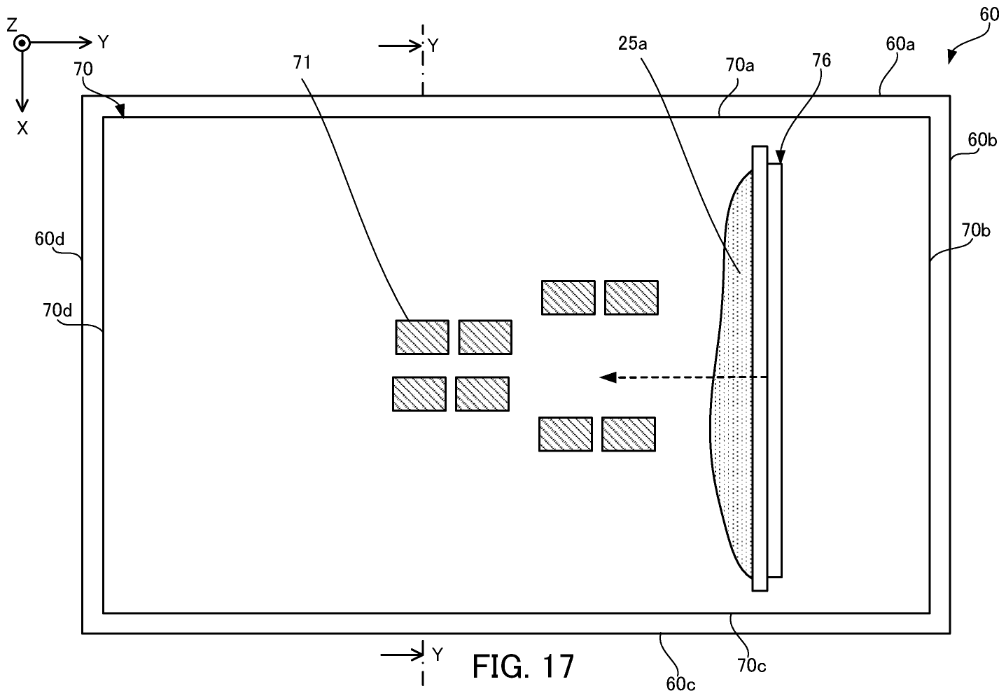

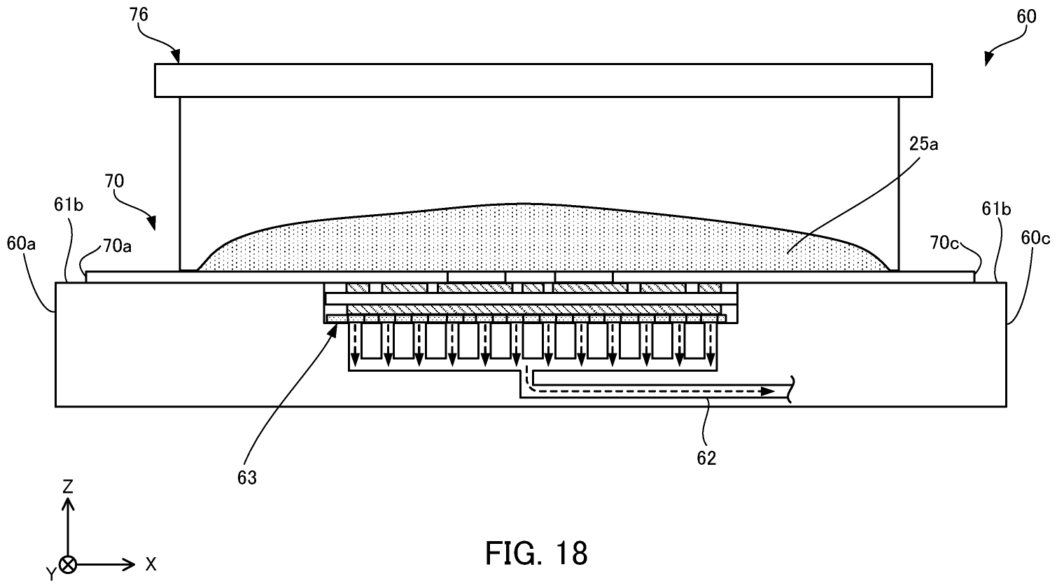

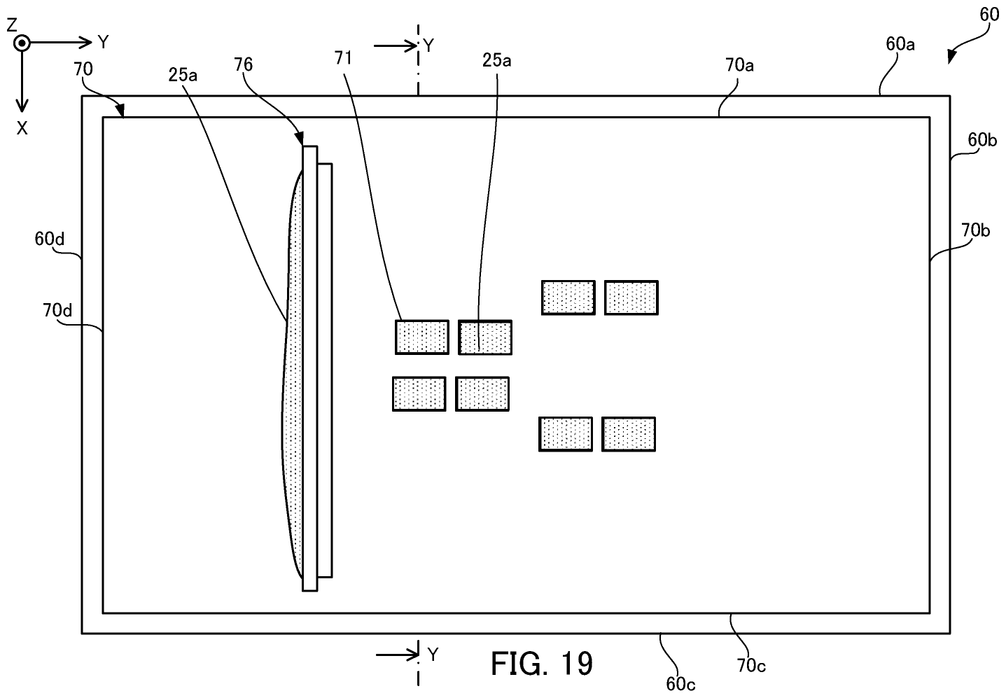

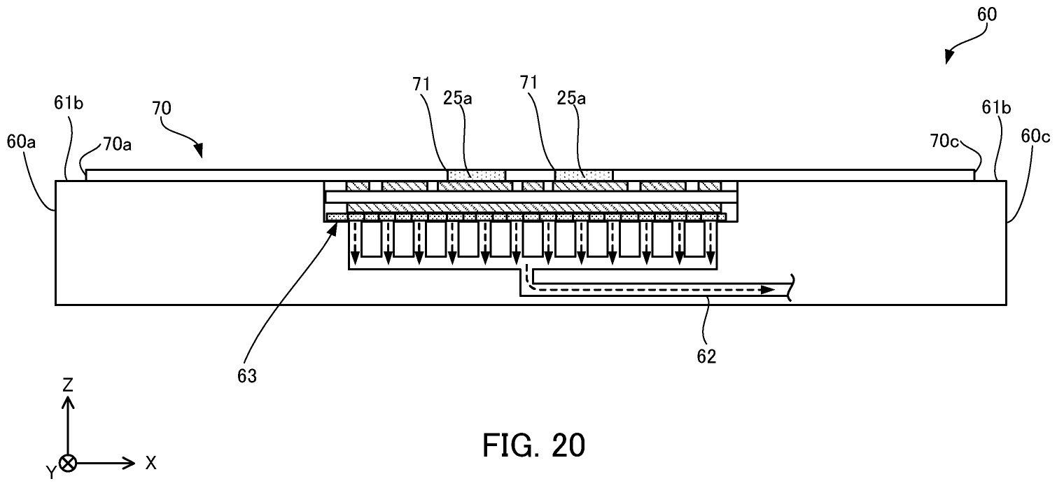

Then, an application step of applying a bonding material to the insulated circuit substrate 20 using the mask 70 is executed (step S2f). The application step will be described with reference to FIGS. 17 to 20. FIGS. 17 and 19 are plan views illustrating the application step of the semiconductor unit assembly step according to the first embodiment. FIGS. 18 and 20 are side sectional views illustrating the application step of the semiconductor unit assembly step according to the first embodiment. In this connection, FIGS. 17 and 18 illustrate the state before the transfer of the bonding material using a squeegee, whereas FIGS. 19 and 20 illustrate the state after the transfer of the bonding material using the squeegee. FIGS. 18 and 20 are sectional views taken along the dashed-dotted lines Y-Y of FIGS. 17 and 19, respectively.

For example, a bonding material 25a before curing is placed adjacent to the side 70b on the front surface of the mask 70 so as to extend from the side 70a to the side 70c. A squeegee 76 is set on the side of the bonding material 25a closer to the side 70b on the front surface of the mask 70, and then is slid toward the side 70d (in the −Y direction) (FIGS. 17 and 18). When the squeegee 76 is slid over all the transfer openings 71 of the mask 70 to the side 70d, the bonding material 25a fills all the transfer openings 71 (FIGS. 19 and 20).

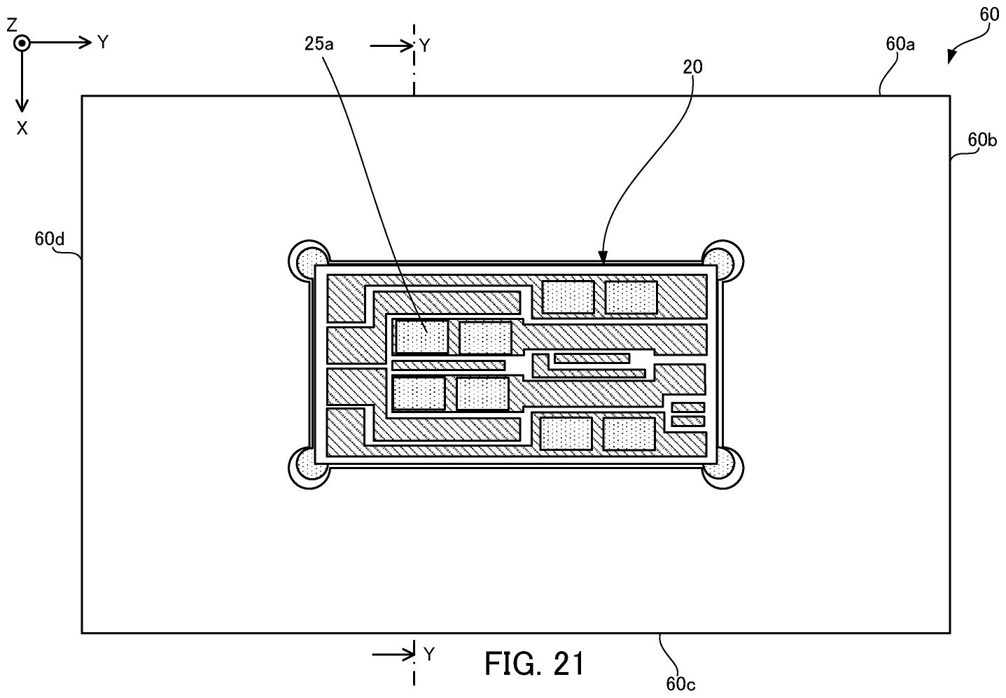

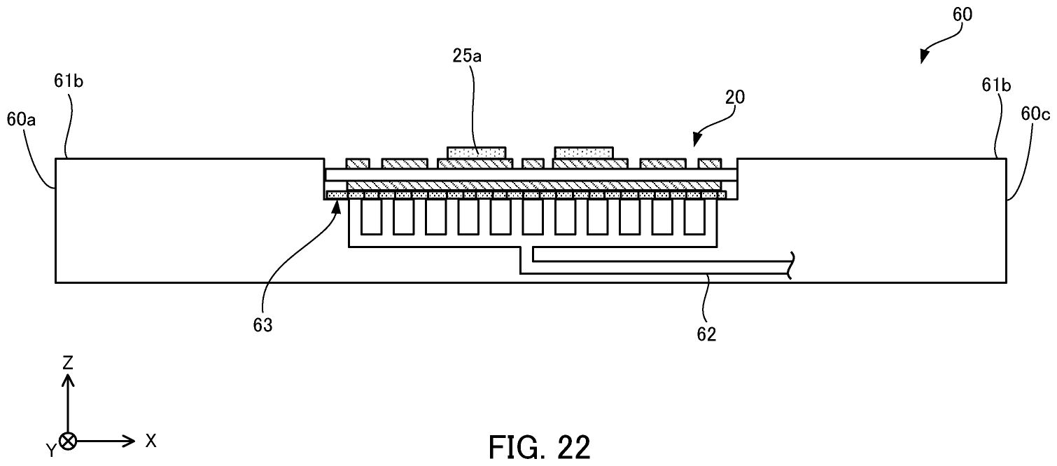

Then, a mask removal step of removing the mask 70 (step S2g) and a suction stop step of stopping suction (step S2h) are executed in order. The mask removal step and the suction stop step will be described with reference to FIGS. 21 and 22. FIG. 21 is a plan view illustrating the mask removal step and suction stop step of the semiconductor unit assembly step according to the first embodiment. FIG. 22 is a side sectional view illustrating the mask removal step and suction stop step of the semiconductor unit assembly step according to the first embodiment. In this connection, FIG. 22 is a sectional view taken along the dashed-dotted line Y-Y of FIG. 21.

When the mask 70 is removed, the bonding material 25a is transferred to the circuit patterns 23a to 23d of the insulated circuit substrate 20 via the transfer openings 71 of the mask 70. The shapes of the transferred bonding material 25a correspond to those of the transfer openings 71. Then, the suction device 65 is stopped to stop sucking the insulated circuit substrate 20.

Then, a detachment step of detaching the insulated circuit substrate 20 from the base 60 is executed (step S2i). The insulated circuit substrate 20 with the transferred bonding material 25a is taken out of the setting space 61a7 of the base 60. Then, a semiconductor chip setting step of setting the semiconductor chips 30a to 30d on the insulated circuit substrate 20 via the bonding material 25a is executed (step S2j). For example, the insulated circuit substrate 20 is set on a chip mounting device, and then the semiconductor chips 30a to 30d are set on the bonding material 25a.

Then, a semiconductor chip bonding step of bonding the semiconductor chips 30a to 30d to the insulated circuit substrate 20 is executed (step S2k). By heating and applying pressure from above the semiconductor chips 30a to 30d, the semiconductor chips 30a to 30d are bonded to the circuit patterns 23a to 23d of the insulated circuit substrate 20 via the cured bonding material 25. In addition, the lead frames 40a to 40d are bonded to connect the output electrodes 32a to 32d of the semiconductor chips 30a to 30d to the circuit patterns 23c, 23e, 23d, and 23f, respectively. In the manner described above, the semiconductor unit 10 illustrated in FIG. 3 is manufactured.

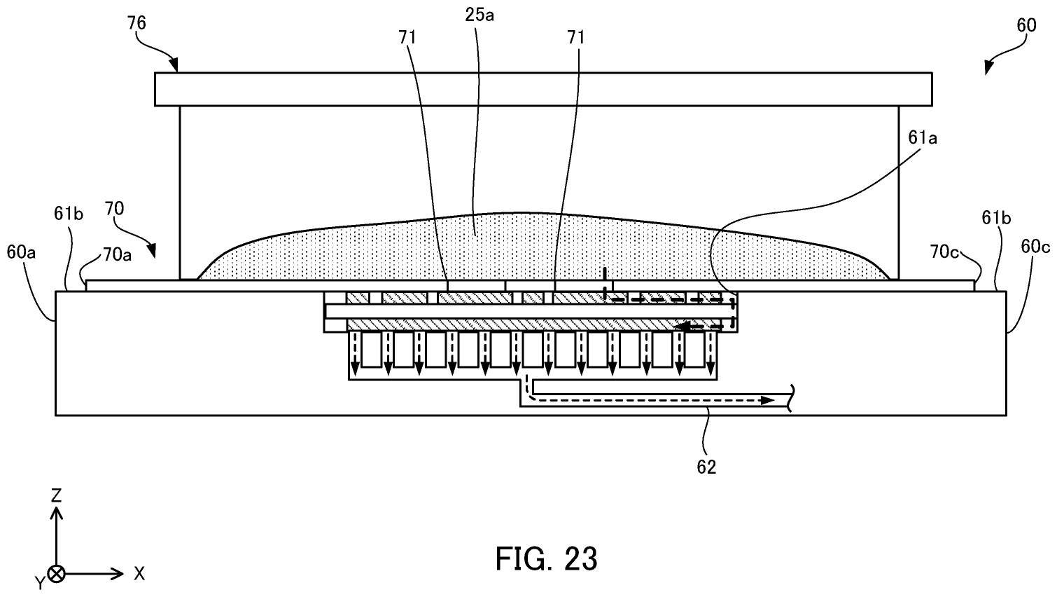

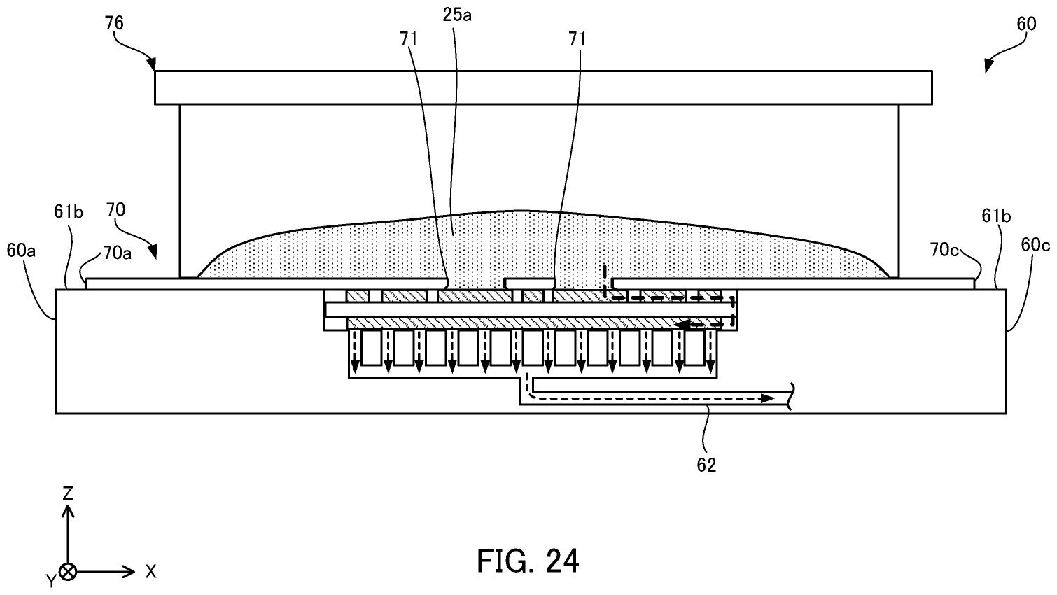

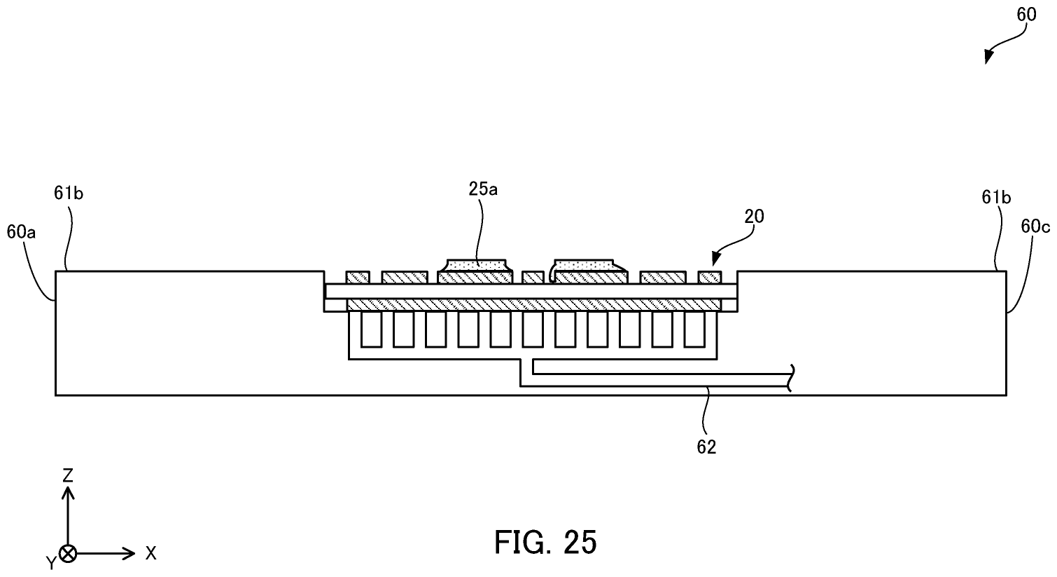

Now, as a first reference example for the first embodiment, a case will be described with reference to FIGS. 23 to 25, where the insulated circuit substrate 20 is set directly in the stage region 61a of the base 60 without setting the elastic sheet 63 in the stage region 61a, and then the bonding material 25a is applied in the semiconductor unit assembly step. FIGS. 23 and 24 are side sectional views illustrating an application step of a semiconductor unit assembly step according to the first reference example. FIG. is a side sectional view illustrating a mask removal step and suction stop step of the semiconductor unit assembly step according to the first reference example. In this connection, FIG. 23 corresponds to the sectional view of FIG. 18, and FIG. 24 is a sectional view illustrating the situation where the squeegee 76 is passing over the transfer openings 71 of the mask 70. FIG. 25 corresponds to the sectional view of FIG. 22.

In the semiconductor unit assembly step of the first reference example, step S2b and subsequent steps of the flowchart illustrated in FIG. 6 are executed in order. More specifically, without the execution of the elastic sheet setting step (step S2a), step S2b is executed where the insulated circuit substrate 20 is set directly in the stage region 61a of the base 60. After that, step S2c and subsequent steps are executed in order.

Then, the application step S2f of applying a bonding material to the insulated circuit substrate 20 using the mask 70 is executed. In this application step, the bonding material 25a before curing is placed adjacent to the side 70b on the front surface of the mask 70 so as to extend from the side 70a to the side 70c, as in the first embodiment (see FIGS. 17 and 23).

At this time, the insulated circuit substrate 20 is sucked from the plurality of suction holes 61a5 of the stage region 61a. While the insulated circuit substrate 20 is kept flat, the insulated circuit substrate 20 does not closely adhere to the stage region 61a completely, but has a slight gap from the stage region 61a. Therefore, during the suction from the plurality of suction holes 61a5, suction paths through the gap between the insulated circuit substrate 20 and the stage region 61a and the gap between the insulated circuit substrate 20 and the inner surfaces 61a1 to 61a4 to the transfer openings 71 are generated. As an example, FIG. 23 illustrates a bold dashed line representing a suction path through the gap between the insulated circuit substrate 20 and the stage region 61a and the gap between the insulated circuit substrate 20 and the inner surface 61a1 to a transfer opening 71.

The squeegee 76 is set on the side of the bonding material 25a closer to the side 70b on the front surface of the mask 70, and is slid toward the side 70d (in the −Y direction). When the squeegee 76 passes over all the transfer openings 71 of the mask 70 and moves to the side 70d, the bonding material 25a fills all the transfer openings 71 (see FIG. 24).

At this time, since the suction paths from the transfer openings 71 to the plurality of suction holes 61a5 are generated, the bonding material 25a filling the transfer openings 71 is sucked along the suction paths. Therefore, the bonding material 25a in the transfer openings 71 spreads beyond the intended application regions.

Then, the mask removal step of removing the mask 70 (step S2g) and the suction stop step of stopping the suction (step S2h) are executed in order. When the mask 70 is removed, the bonding material 25a is transferred to the circuit patterns 23a to 23d of the insulated circuit substrate 20 via the transfer openings 71 of the mask 70. Since the transferred bonding material 25a has been sucked along the suction paths, the bonding material 25a does not correspond in shape to the transfer openings 71 but spreads over the circuit patterns 23a to 23i. For example, the bonding material 25a may connect between the circuit patterns 23a to 23i, depending on how the bonding material 25a spreads. This causes electrical failure. After that, the suction device 65 is stopped to stop sucking the insulated circuit substrate 20 (FIG. 25).

In thus assembled semiconductor unit 10, the bonding material 25 spreads beyond the intended application regions, which may reduce the reliability of the semiconductor unit 10 and the semiconductor module 1 including the semiconductor unit 10.

The bonding material application apparatus 50 of the first embodiment includes the base 60, suction device 65, and elastic sheet 63. The base 60 has the front surface 61 where the stage region 61a for placing the insulated circuit substrate 20 that is an application target member is set, and also has a suction hole 61a5 formed in the stage region 61a of the front surface 61. The suction device 65 creates suction through the suction hole 61a5 in the direction from the front surface 61 toward the opposite side of the front surface 61. The elastic sheet 63 is provided in the stage region 61a and has a through hole 63b that communicates with the suction hole 61a5 and continuously surrounds the outer periphery of the suction hole 61a5 in a ring shape. The insulated circuit substrate 20 is placed on the elastic sheet 63. In this bonding material application apparatus 50, the outer periphery of the suction hole 61a5 is continuously surrounded in a ring shape by the elastic sheet 63. When the insulated circuit substrate 20 is sucked from the suction hole 61a5, the elastic sheet 63 and the insulated circuit substrate 20 closely adhere to each other, so that the insulated circuit substrate 20 is kept flat. Therefore, the generation of suction paths through the gap between the insulated circuit substrate 20 and the stage region 61a and the gap between the insulated circuit substrate 20 and the inner surfaces 61a1 to 61a4 to the transfer openings 71 is prevented. Therefore, when the bonding material 25a is transferred via the transfer openings 71 of the mask 70 onto the insulated circuit substrate 20 being sucked from the suction hole 61a5, the spreading of the bonding material 25a is prevented. Thus, the occurrences of electrical failure and other faults are prevented, and a reduction in the reliability of the semiconductor module 1 is prevented.

Especially, in the case where a sintered material is used as the bonding material 25 (bonding material 25a), it is difficult to adjust the viscosity because the sintered material does not contain flux. With the application method using the bonding material application apparatus 50, it is possible to apply such a bonding material 25 (bonding material 25a) to intended application regions of the insulated circuit substrate 20 properly.

In the first embodiment, the elastic sheet 63 continuously surrounds the outer periphery of each suction hole 61a5 in a ring shape in order to prevent the generation of suction paths from the suction holes 61a5 to the transfer openings 71 of the mask 70. How to surround the suction holes 61a5 by the elastic sheet 63 is not limited to the case described in the first embodiment.

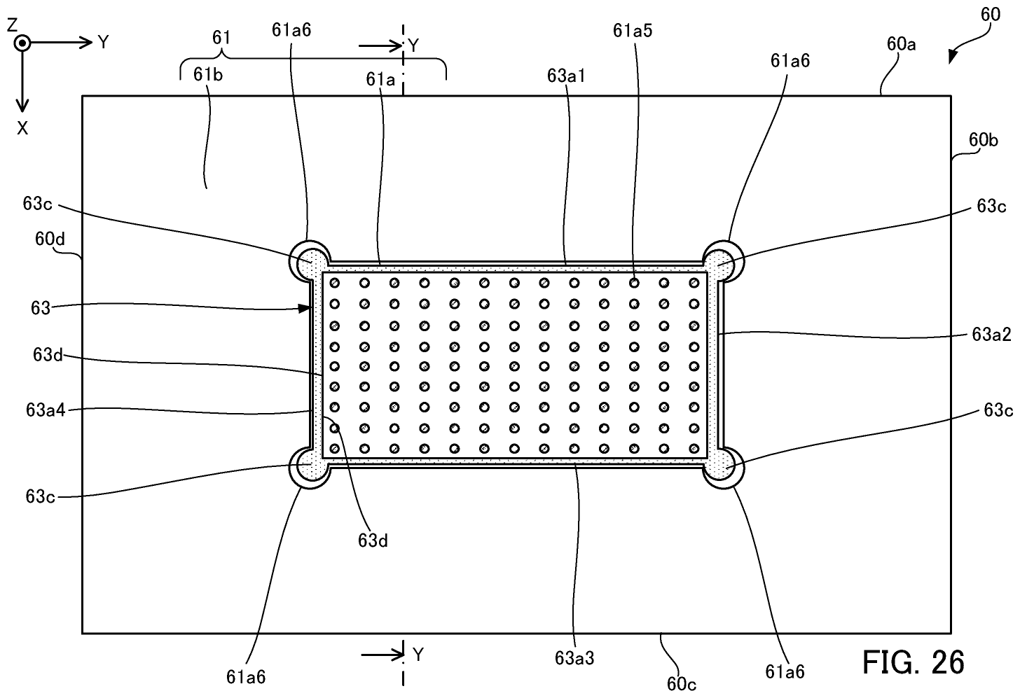

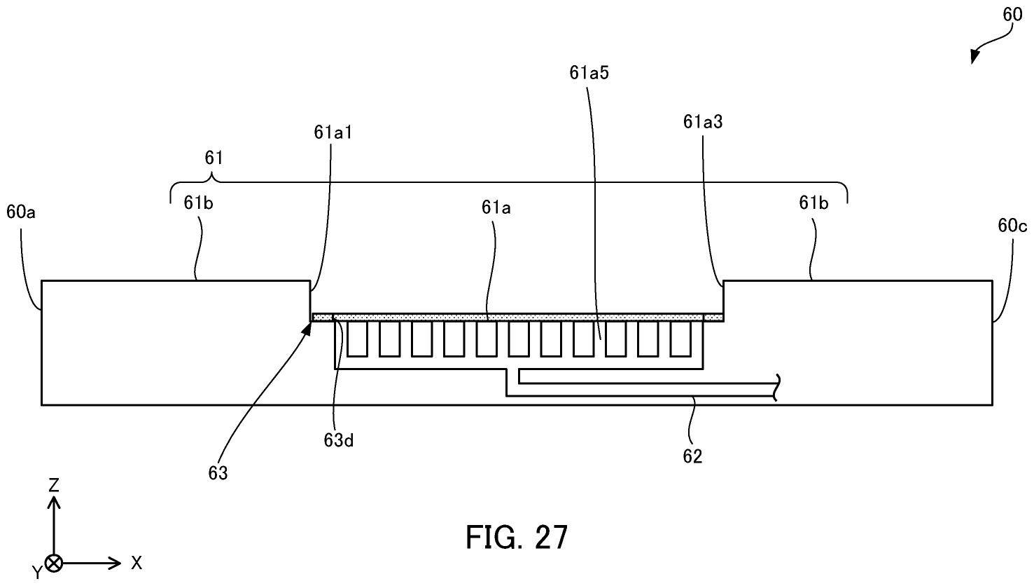

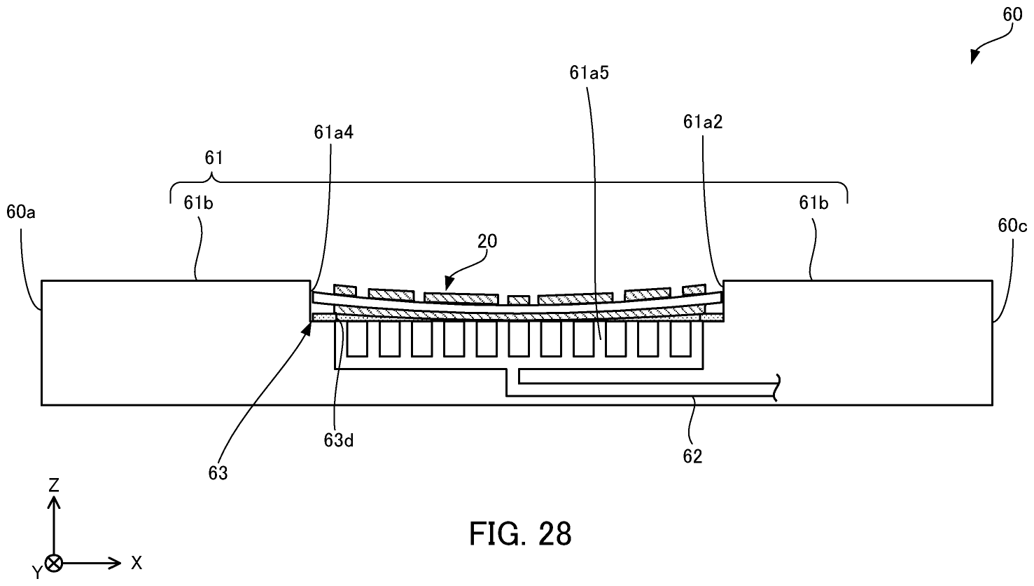

Now, a second reference example that is an undesirable example of the elastic sheet 63 will be described with reference to FIGS. 26 to 28. FIG. 26 is a plan view illustrating an elastic sheet setting step of a semiconductor unit assembly step according to the second reference example. FIG. 27 is a side sectional view illustrating the elastic sheet setting step of the semiconductor unit assembly step according to the second reference example. FIG. 28 is a side sectional view illustrating an insulated circuit substrate setting step of the semiconductor unit assembly step according to the second reference example.

As illustrated in FIGS. 26 and 27, an elastic sheet 63 used in the second reference example has a frame shape with an opening 63d at the central portion thereof so as to continuously surround the outer periphery of the stage region 61a in a loop shape. This elastic sheet 63 surrounds the plurality of suction holes 61a5, and it is expected that the insulated circuit substrate 20 placed on the elastic sheet 63 closely adheres to the elastic sheet 63 and therefore the generation of suction paths from the plurality of suction holes 61a5 to the transfer openings 71 of the mask 70 is prevented.

As a matter of fact, however, if the insulated circuit substrate 20 is placed on the above elastic sheet 63 and is sucked, the outer edge portion of the rear surface of the insulated circuit substrate 20 is supported by the outer edge of the elastic sheet 63, and the central portion of the insulated circuit substrate 20 is sucked to the stage region 61a, so that the insulated circuit substrate 20 is warped in a downward convex shape, as illustrated in FIG. 28. If the insulated circuit substrate 20 is warped, it is difficult to apply the bonding material 25a using the mask 70 properly.

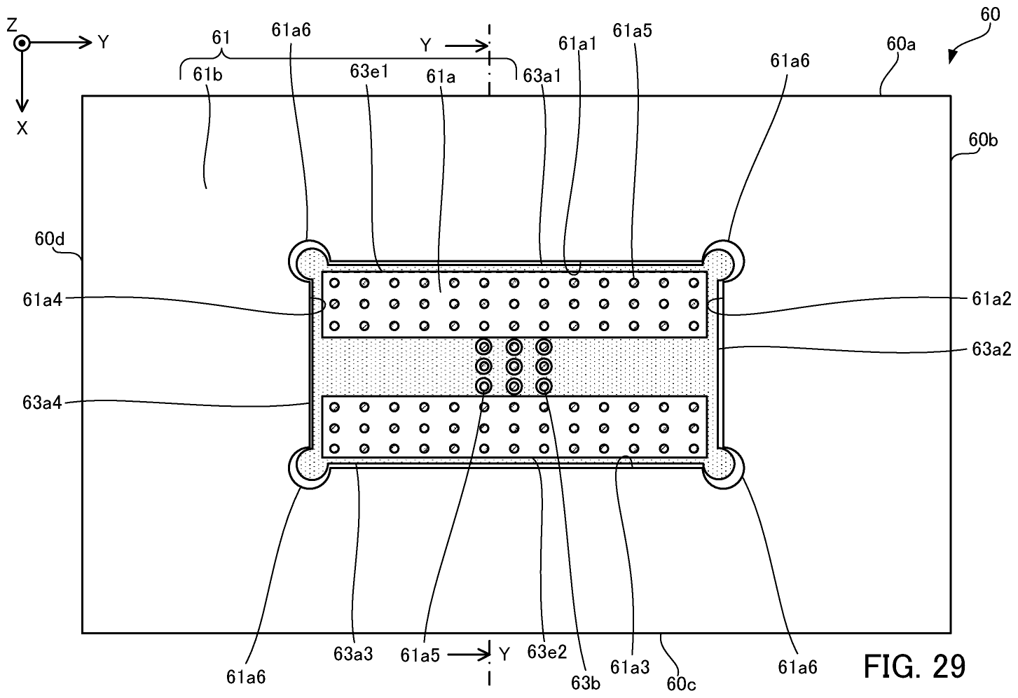

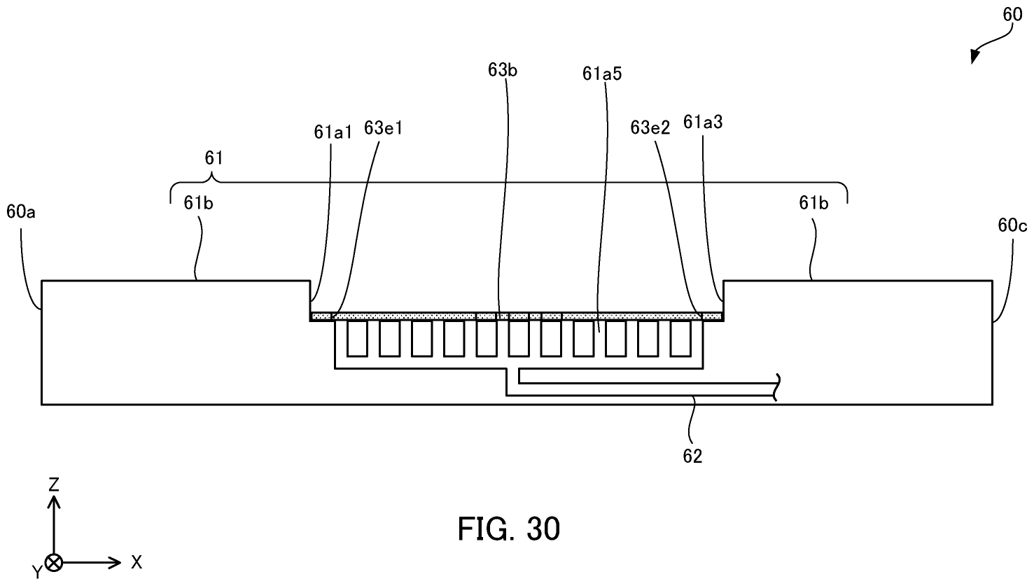

To avoid this, for example, the following elastic sheet 63 may be used. This case will be described with reference to FIGS. 29 and 30. FIG. 29 is a plan view illustrating a different elastic sheet that is used in the semiconductor unit assembly step according to the first embodiment. FIG. 30 is a side sectional view illustrating the different elastic sheet that is used in the semiconductor unit assembly step according to the first embodiment. In this connection, FIG. 30 is a sectional view taken along the dashed-dotted line Y-Y of FIG. 29.

The elastic sheet 63 has at least one opening (second opening). In this case, there are two openings 63e1 and 63e2 on both sides of the central portion, leaving the central portion, for example. The central portion of the elastic sheet 63 extends in parallel to the sides 63a1 and 63a3 and connects the centers of the sides 63a2 and 63a4 together. The central portion of the elastic sheet 63 has a plurality of through holes (first openings) 63b. A plurality of suction holes (first suction holes) 61a5 are located in this central portion. In this central portion, each through hole 63b is located at a position immediately above one suction hole 61a5. The stage region 61a also has another plurality of suction holes 61a5 and they are located within the openings 63e1 and 63e2. The suction can be applied to the insulated circuit substrate 20 through respective suction holes 61a5 disposed within respective through holes 63b when viewed from the Z direction, and through another suction holes 61a5 disposed within the openings 63e1 and 63e2 when viewed from the Z direction.

When the insulated circuit substrate 20 is placed on this elastic sheet 63 and is sucked, the insulated circuit substrate 20 is sucked to the stage region 61a while the outer edge portion of the rear surface of the insulated circuit substrate 20 is supported by the outer edge of the elastic sheet 63. At this time, the central portion of the rear surface of the insulated circuit substrate 20 closely adheres to the central portion of the elastic sheet 63 due to the suction through the first suction holes 61a5, so that the insulated circuit substrate 20 is kept flat. Therefore, it is possible to prevent the generation of suction paths from the plurality of suction holes 61a5 and openings 63e1 and 63e2 to the transfer openings 71 of the mask 70.

Therefore, in the case where the elastic sheet 63 is formed in a frame shape as illustrated in FIG. 26, the elastic sheet 63 may have openings in areas excluding the central portion, in order to prevent the insulated circuit substrate 20 from being warped in a downward convex shape during suction. The number of openings in this case is not limited to two. In addition, the shape of each opening in plan view is not limited to a rectangular shape but may be a circular shape, an elliptical shape, or any other shape.

### Second Embodiment

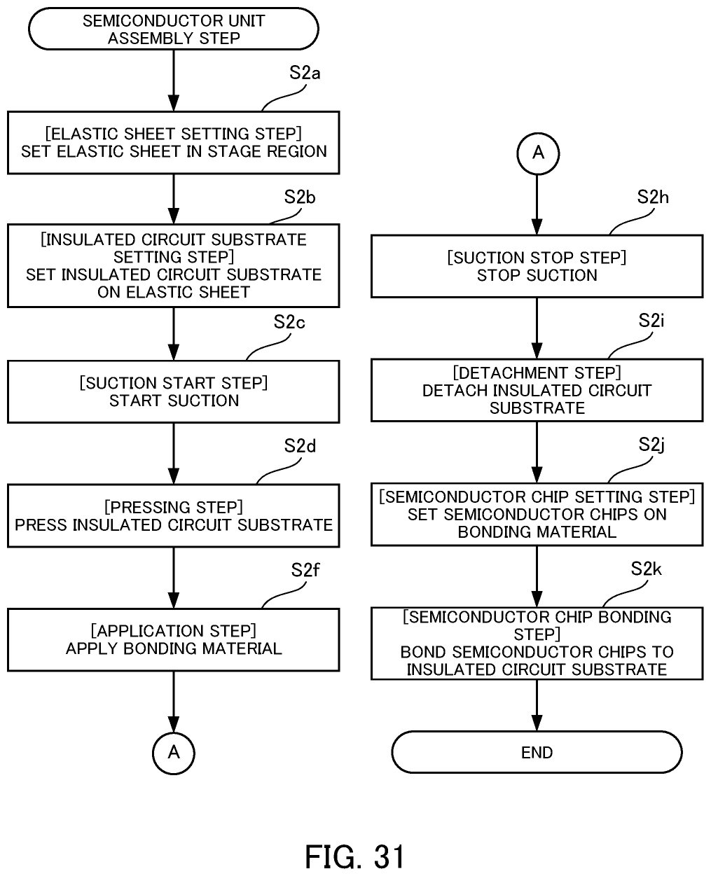

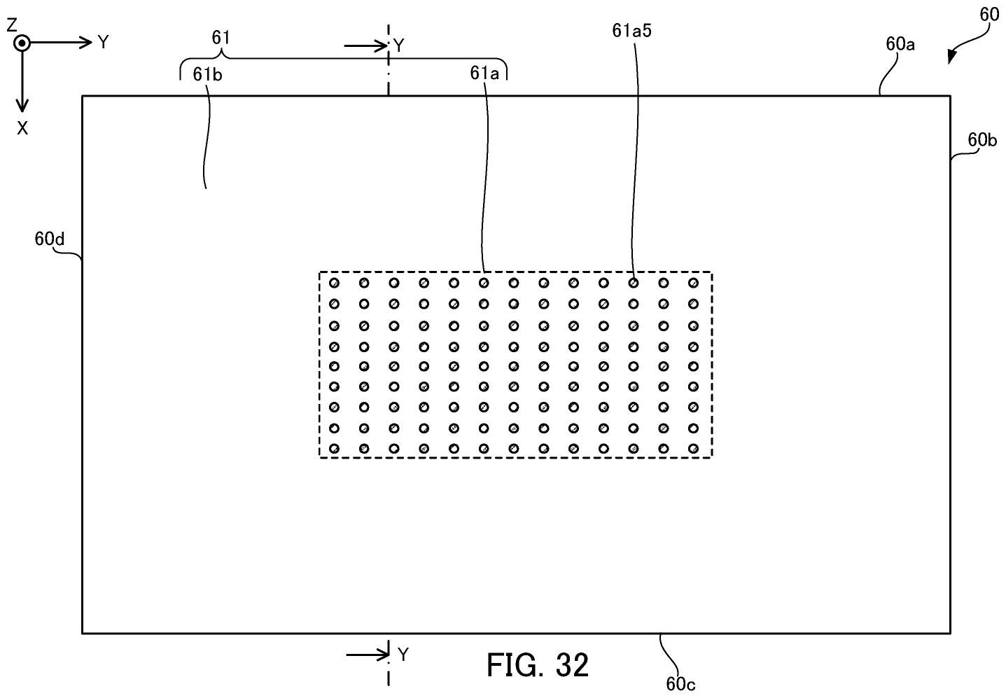

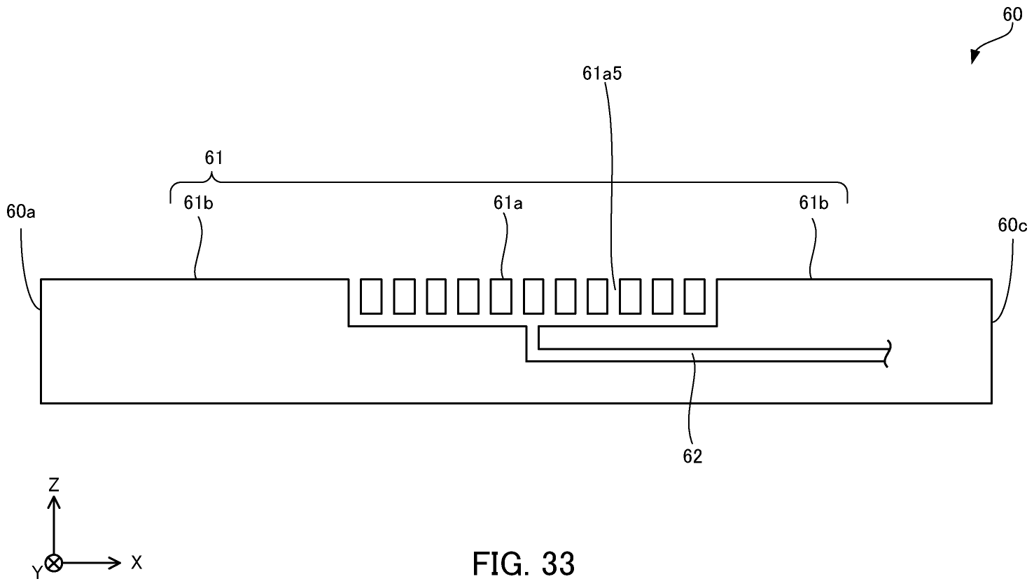

In a second embodiment, the front surface 61 of a base 60 included in a bonding material application apparatus 50 has a stage region 61a and a support region 61b that are flush with each other. A semiconductor unit assembly step using this base 60 will be described with reference to FIG. 31. In addition, the base 60 used in this step will be described with reference to FIGS. 32 and 33. FIG. 31 is a flowchart illustrating a semiconductor unit assembly step according to the second embodiment. FIG. 32 is a plan view of the front surface of the base according to the second embodiment. FIG. 33 is a side sectional view of the base according to the second embodiment. In this connection, FIG. 33 is a sectional view taken along the dashed-dotted line Y-Y of FIG. 32.

The bonding material application apparatus 50 includes the base 60, a suction device 65, and an elastic sheet 63. The base 60 of the second embodiment has the stage region 61a and support region 61b that are flush with each other in the front surface 61 thereof. The other configuration of the base 60 is the same as that of the first embodiment. In addition, the suction device 65 and elastic sheet 63 are the same as those used in the first embodiment. In this case, however, the fixing portions 63c are not formed in the elastic sheet 63.

With this bonding material application apparatus 50, the semiconductor unit assembly step is executed in the following manner. In this connection, the description on the same steps in the semiconductor unit assembly step of the second embodiment as in the semiconductor unit assembly step of the first embodiment will be simplified.

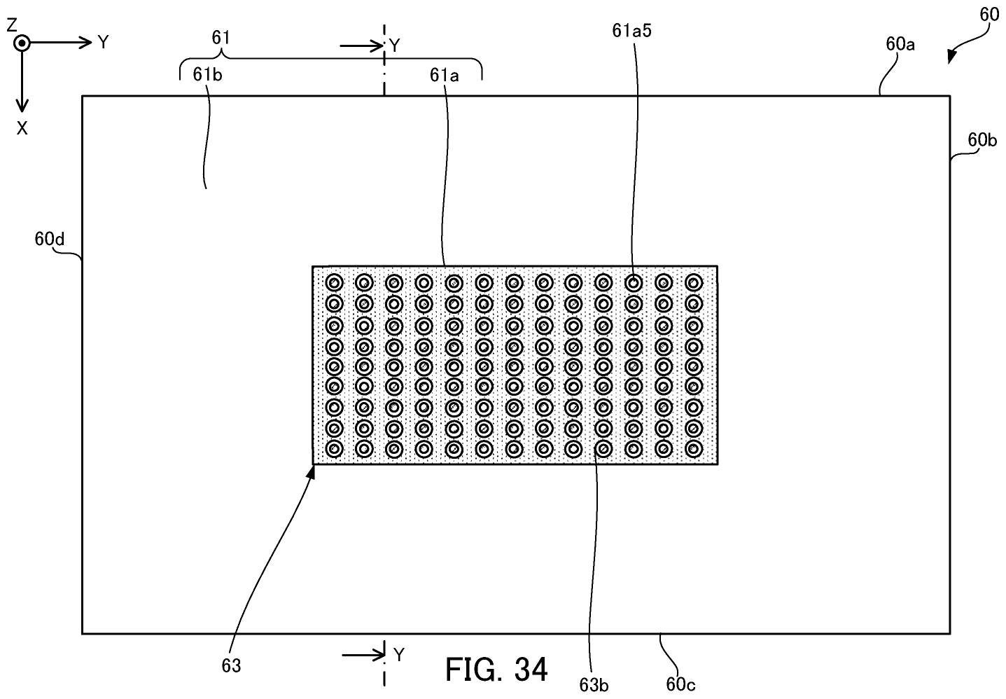

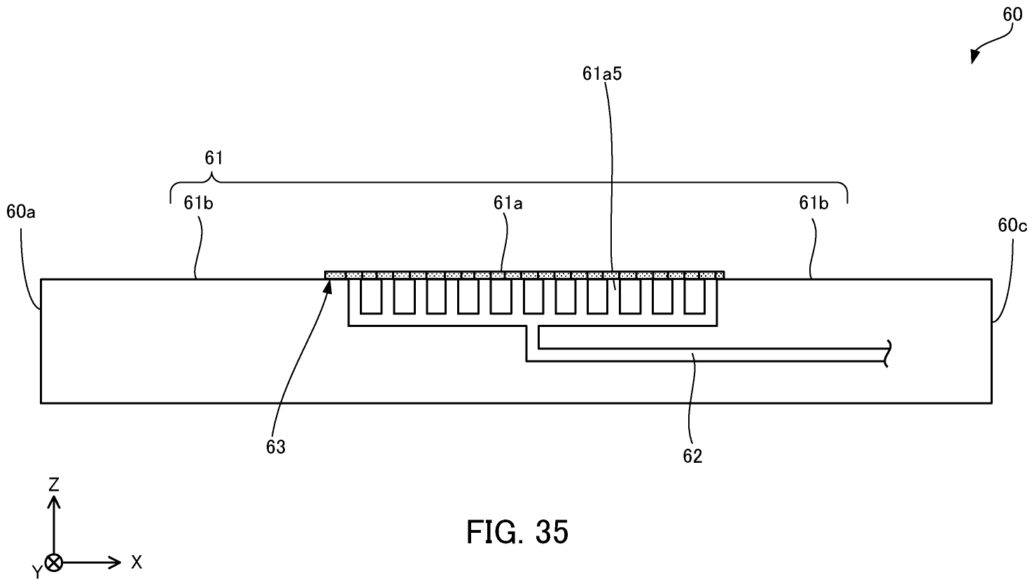

First, an elastic sheet setting step of setting the elastic sheet 63 in the stage region 61a of the base 60 is executed (step S2a). The elastic sheet setting step will be described with reference to FIGS. 34 and 35. FIG. 34 is a plan view illustrating the elastic sheet setting step of the semiconductor unit assembly step according to the second embodiment. FIG. 35 is a side sectional view illustrating the elastic sheet setting step of the semiconductor unit assembly step according to the second embodiment. In this connection, FIG. 35 is a sectional view taken along the dashed-dotted line Y-Y of FIG. 34.

The elastic sheet 63 is set in the stage region 61a on the front surface 61 of the base 60, as illustrated in FIGS. 34 and 35. The size of the elastic sheet 63 in plan view may be the same as or greater than that of the stage region 61a.

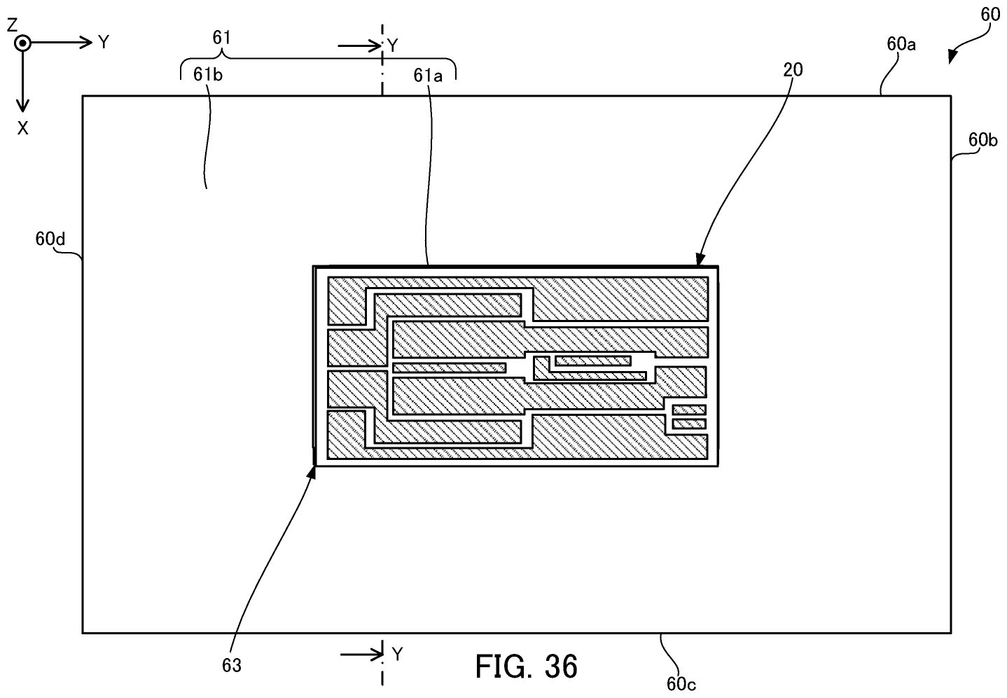

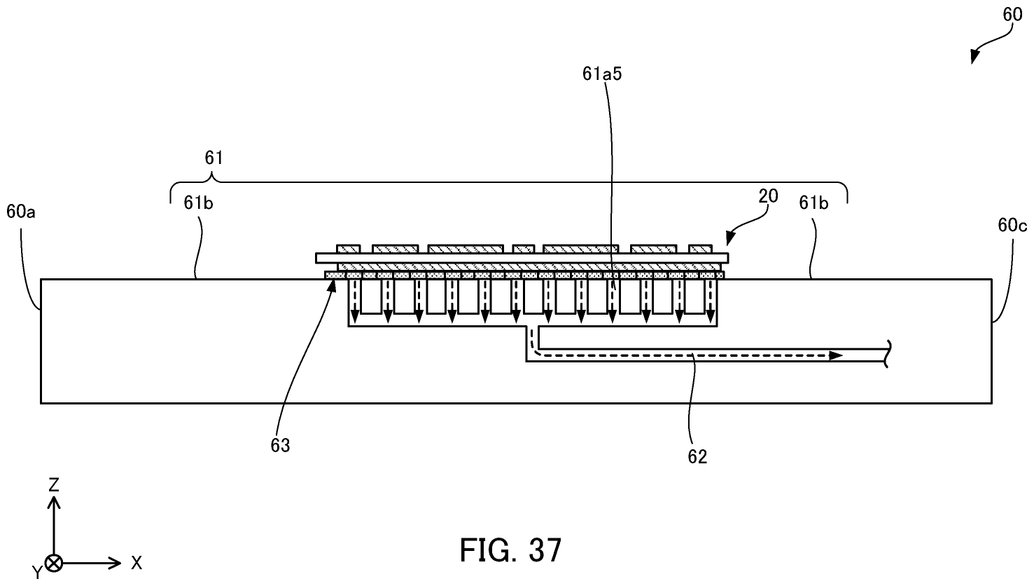

Then, an insulated circuit substrate setting step of setting the insulated circuit substrate 20 on the elastic sheet 63 (step S2b) and a suction start step of starting to suck the set insulated circuit substrate 20 (step S2c) are executed. The insulated circuit substrate setting step and suction start step will be described with reference to FIGS. 36 and 37. FIG. 36 is a plan view illustrating the insulated circuit substrate setting step and suction start step of the semiconductor unit assembly step according to the second embodiment. FIG. 37 is a side sectional view illustrating the insulated circuit substrate setting step and suction start step of the semiconductor unit assembly step according to the second embodiment. In this connection, FIG. 37 is a sectional view taken along the dashed-dotted line of FIG. 36.

The insulated circuit substrate 20 is set in the stage region 61a via the elastic sheet 63. The suction device 65 is driven to start to suck the insulated circuit substrate 20 from the plurality of suction holes 61a5 via the plurality of through holes 63b of the elastic sheet 63. When the amount of suction per unit time has reached a predetermined value after the start of the suction, the amount of suction is kept. Since the insulated circuit substrate 20 warped in an upward convex shape or in a downward convex shape is sucked, the rear surface of the insulated circuit substrate 20 is drawn toward the stage region 61a, so as to reduce the gap between the insulated circuit substrate 20 and the elastic sheet 63 set in the stage region 61a or eliminate the gap to achieve close adherence therebetween. In this connection, FIGS. 36 and 37 illustrate the case where the insulated circuit substrate 20 closely adheres to the elastic sheet 63 set in the stage region 61a.

Then, a pressing step of pressing the front surface of the insulated circuit substrate 20 toward the stage region 61a is executed (step S2d) while the insulated circuit substrate 20 is sucked. As in the first embodiment, in the case where the insulated circuit substrate 20 being sucked at step S2c closely adheres to the elastic sheet 63 without any gap therebetween, the pressing step S2d may be omitted. In the case where the pressing step is executed, a weight 75 may be used, as in the first embodiment. In this case, to prevent the weight 75 from pressing the insulated circuit substrate 20 too much, for example, the weight 75 may be formed in a box shape with the depth approximately equal to the thickness of the insulated circuit substrate 20 and be disposed on the support region 61b so as to cover the insulated circuit substrate 20.

Once the insulated circuit substrate 20 closely adheres to the elastic sheet 63 at the suction start step (step S2c) or pressing step (step S2d), the rear surface of the insulated circuit substrate 20 is sucked from the plurality of suction holes 61a5 of the stage region 61a via the plurality of through holes 63b of the elastic sheet 63. That is, the suction paths from the suction holes 61a5 lead only to the rear surface of the insulated circuit substrate 20. Therefore, the insulated circuit substrate 20 is kept flat reliably.

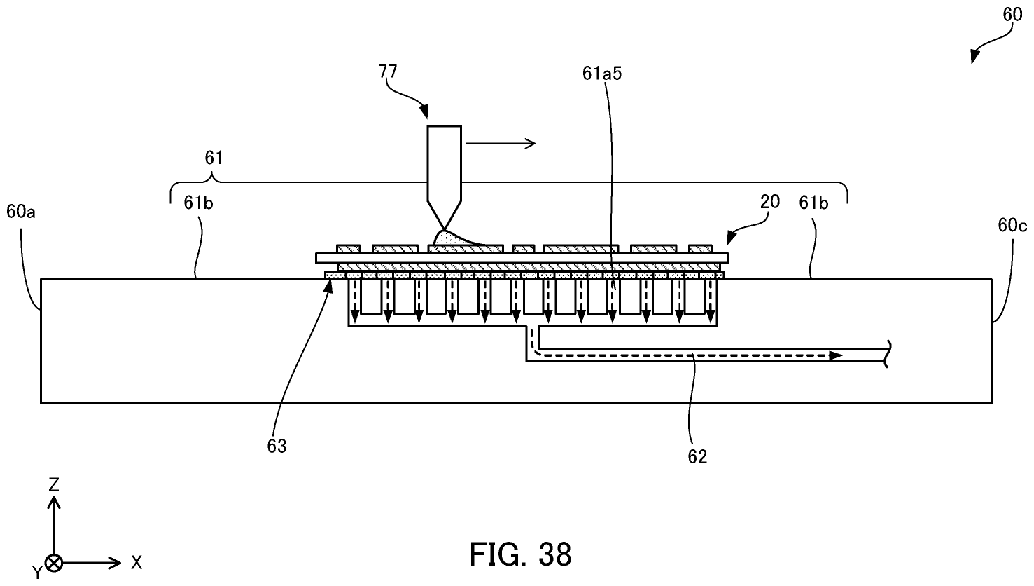

Then, an application step of applying a bonding material to the insulated circuit substrate 20 is executed (step S2f). The application step will be described with reference to FIG. 38. FIG. 38 is a side sectional view illustrating the application step of the semiconductor unit assembly step according to the second embodiment. In this connection, FIG. 38 is a sectional view of a part corresponding to that illustrated in FIG. 20 of the first embodiment.

In the application step of the second embodiment, the bonding material 25a is applied, not using the mask 70 but using a dispenser 77, for example. The bonding material 25a is dispensed from the dispenser 77 onto the chip regions 23a1 to 23d1 of the circuit patterns 23a to 23d, and is spread over the entire chip regions 23a1 to 23d1. Since the insulated circuit substrate 20 is kept flat, the dispenser 77 is able to apply the bonding material 25a in a substantially uniform thickness to the chip regions 23a1 to 23d1 of the circuit patterns 23a to 23d.

Note that, in the case of applying the bonding material 25a to the insulated circuit substrate 20 warped in an upward convex shape or in a downward convex shape using the dispenser 77, it is difficult to apply the bonding material 25a in a substantially uniform thickness because the chip regions 23a1 to 23d1 of the circuit patterns 23a to 23d have curved surfaces.

After the bonding material 25a is applied to the insulated circuit substrate 20 in the manner described above, a suction stop step of stopping the suction (step S2h) and a detachment step of detaching the insulated circuit substrate 20 from the base 60 (step S2i) are executed, as in the first embodiment. After that, a semiconductor chip setting step of setting the semiconductor chips 30a to 30d on the insulated circuit substrate 20 via the bonding material 25a (step S2j) and a semiconductor chip bonding step of bonding the semiconductor chips 30a to 30d to the insulated circuit substrate 20 (step S2k) are executed. Through the above steps, the semiconductor unit 10 illustrated in FIG. 3 is manufactured.

In the bonding material application apparatus 50 of the second embodiment, the elastic sheet 63 continuously surrounds the outer periphery of each suction hole 61a5 in a ring shape. When the insulated circuit substrate 20 is sucked from the suction holes 61a5, the elastic sheet 63 and the insulated circuit substrate 20 closely adhere to each other. Therefore, the insulated circuit substrate 20 is sucked from the suction holes 61a5 via the through holes 63b reliably. Thus, the insulated circuit substrate 20 is kept substantially flat. This makes it possible to apply the bonding material 25a to intended regions while preventing the bonding material 25a from spreading beyond the intended regions. Thus, the occurrences of electrical failure and other faults are prevented, and a reduction in the reliability of the semiconductor module 1 is prevented.

According to the disclosed techniques, it is possible to apply a bonding material to predetermined application regions properly and to thereby prevent a reduction in the reliability of a device including the bonding material.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A bonding material application apparatus that applies a bonding material to a target member while fixing the target member by applying suction thereto, the bonding material application apparatus comprising:
a base having a stage region at a front side thereof, and a plurality of suction holes in the stage region;
an elastic member provided in the stage region, the elastic member having a plurality of through holes, each through hole being disposed at a position immediately above a corresponding one of the plurality of suction holes when viewed from a suction direction from the front side of the base to a rear side of the base; and
a suction unit configured to apply the suction for suctioning the target member to be placed in the stage region in the suction direction through suction holes among the plurality of suction holes, which are respectively disposed at positions immediately below respective ones of the plurality of through holes, thereby to fix the target member to the stage region by the suction via the elastic member.

2. The bonding material application apparatus according to claim 1, wherein the elastic member is sheet-shaped.

3. The bonding material application apparatus according to claim 2, wherein in a plan view of the bonding material application apparatus, the elastic member corresponds in shape to the stage region of the base.

4. The bonding material application apparatus according to claim 3, wherein
the base further includes a support region outside the stage region at the front side thereof, and
the stage region is recessed toward the rear side of the base such that a surface of the stage region is closer to the rear side of the base than is a surface of the support region.

5. The bonding material application apparatus according to claim 4, wherein a depth of the stage region from the surface of the support region is set to be equal to a total thickness of thicknesses of the target member and the elastic member.

6. The bonding material application apparatus according to claim 5, wherein
the stage region has a rectangular shape corresponding to a shape of the target member in the plan view.

7. The bonding material application apparatus according to claim 6, wherein in the stage region of the base, the plurality of through holes are provided in an area set to correspond to a specific area of the target member when the target member is placed on the stage region.

8. The bonding material application apparatus according to claim 6, further comprising a mask including a transfer opening provided at a position set to correspond to an application region where a bonding material is to be applied, the mask being disposed on the front surface of the base such that the mask at least partially covers the stage region, the support region supporting the mask.

9. The bonding material application apparatus according to claim 6, wherein
the stage region of the base has a recess at at least one of four corners thereof that is recessed outward toward an outer periphery of the support region in a direction parallel to the surface of the support region, and
the elastic member includes a fixing portion at a corner thereof that is located at a position corresponding to a position of the recess, the fixing portion having a shape that fits the recess.

10. The bonding material application apparatus according to claim 5, further comprising a pressing member for pressing in the suction direction toward the rear side of the base the target member to be placed in the stage region.

11. The bonding material application apparatus according to claim 1, wherein the plurality of suction holes includes a plurality of first suction holes and a plurality of second suction holes, and the plurality of through holes are disposed at positions immediately above the plurality of first suction holes, and
a total number of the plurality of through holes is equal to or less than a total number of the plurality of first suction holes and the plurality of second suction holes.

12. The bonding material application apparatus according to claim 1, wherein
the elastic member is provided in plurality, and the plurality of through holes are included in the plurality of elastic members.

13. The bonding material application apparatus according to claim 6, wherein
the elastic member includes an outer edge portion provided on an outer periphery of the stage region of the base, a central portion connecting the centers of opposite sides of the outer edge portion and having the plurality of through holes, and openings provided on both sides of the central portion and extending in parallel to the central portion in the plan view.

14. A bonding material application method, comprising:
preparing a bonding material and a target member;
setting an elastic member on a stage region disposed at a front side of a base, the base having a plurality of suction holes in the stage region, the elastic member having a plurality of through holes, each of which is disposed at a position immediately above a corresponding one of the plurality of suction holes when viewed from a suction direction from the front side of the base to a rear side of the base;
setting the target member on the elastic member;
applying suction to suction the target member placed on the elastic member in the suction direction through suction holes among the plurality of suction holes, which are respectively disposed at positions immediately below respective ones of the plurality of through holes, thereby to fix the target member to the stage region by the suction via the elastic member; and
applying the bonding material to a predetermined application region of the target member while fixing the target member by the suction.

15. The bonding material application method according to claim 14, further comprising pressing the target member by a pressing member in the suction direction toward the rear side of the base before applying the bonding material, and before or after applying the suction to the target member.

16. The bonding material application method according to claim 15, wherein
the base further includes a support region outside the stage region at the front side thereof, and
the stage region is recessed such that a surface of the stage region is closer to the rear side than is a surface of the support region.

17. The bonding material application method according to claim 16, further comprising:
after fixing the target member by the suction and pressing the target member,
releasing the pressing member to press the target member; and
disposing a mask on the front surface of the base such that the mask covers the target member and the support region supports the mask, the mask including a transfer opening disposed at a position corresponding to an application region of the target member where the bonding material is to be applied, wherein
the applying of the bonding material includes transferring the bonding material to the target member via the transfer opening of the mask.

18. The bonding material application method according to claim 14, further comprising:
after setting the target member and before fixing the target member by the suction,
disposing a mask on the front surface of the base to cover the target member, the mask including a transfer opening disposed at a position corresponding to an application region of the target member where the bonding material is to be applied, wherein
the applying of the bonding material includes transferring the bonding material to the target member via the transfer opening of the mask.
